(19) United States
(12) Patent Application Publication
(10) Pub. No.: US 2010/0157693 A1
(43) Pub. Date: Jun. 24, 2010

(54) SEMICONDUCTOR MEMORY DEVICE

(75) Inventors: Takayuki Iwai, Tokyo (JP); Takayuki Miyazaki, Tokyo (JP); Mariko Iizuka, Yokohama-shi (JP)

Correspondence Address: TUROCY & WATSON, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/613,737

(22) Filed: Nov. 6, 2009

(30) Foreign Application Priority Data
Dec. 24, 2008 (JP) 2008-328386

(51) Int. Cl. G11C 5/14; G11C 8/08; G11C 8/10; G11C 7/22; G11C 7/00

(52) U.S. Cl. 365/189.09; 365/230.01; 365/230.06; 365/200; 365/194; 365/222; 365/226

(57) ABSTRACT

A semiconductor memory device comprises a memory cell array including a plurality of word lines, a plurality of bit lines intersecting the plurality of word lines, and a plurality of binary-data holding memory cells arranged at the intersections of the word lines and the bit lines; and a control unit operative to change in the storage capacity of the memory cell array and change in the address space required for access to the memory cell based on a control signal.

### CROSS-REFERENCE TO RELATED APPLICATION

This application is based upon and claims the benefit of priority from the prior Japanese Patent Application No. 2008-328386, filed on Dec. 24, 2008, the entire contents of which are incorporated herein by reference.

### BACKGROUND OF THE INVENTION

1. Field of the Invention

The present invention relates to a semiconductor memory device.

2. Description of the Related Art

In association with downsizing electronics or increasing the performance thereof, low power consumption in a system LSI becomes an important design requirement. An achievement of low power consumption allows a battery-powered system to extend the continuous running time. A high-performance system can simplify cooling and exhausting heat.

A means for achieving low power consumption in the system LSI generally includes a reduction in source voltage. A system LSI has been developed to vary the source voltage and the operating frequency in accordance with the computation ability actually required on operation. A realization of such the system LSI causes a large problem on the operating characteristic of a memory circuit on low source voltage. In general, the memory circuit has a larger deterioration of the performance due to the reduction in source voltage than a logic circuit and a higher lower limit of source voltage for operation than the logic circuit.

In the case of a memory circuit that requires refreshing, such as a DRAM, extended intervals of refreshing during standby can achieve low power consumption. The extended refreshing intervals, however, lead to an increase in risk of dissipating data inevitably. Therefore, to solve this problem, a means has been proposed to relieve data in a memory cell with ECC (Document: T. Nagai et. al., “A 65 nm Low-Power Embedded DRAM with Extended Data-Retention Sleep Mode”, 2006 IEEE International Solid-State Circuits Conference). Namely, at the time of entering standby, the memory circuit generates parity data with ECC, and at the time of exiting from standby, it uses the parity data for error checking and correction. As a result, the reliability of the memory circuit can be improved while the power consumption and processing time for the parity data generation and the error checking and correction is increased. In addition, ECC mounting results in an increase in chip area.

### SUMMARY OF THE INVENTION

In an aspect the present invention provides a semiconductor memory device, comprising: a memory cell array including a plurality of word lines, a plurality of bit lines intersecting the plurality of word lines, and a plurality of binary-data holding memory cells arranged at the intersections of the word lines and the bit lines; and a control unit operative to change in the storage capacity of the memory cell array and change in the address space required for access to the memory cell based on a control signal.

In another aspect the present invention provides a semiconductor memory device, comprising: a plurality of memory cell arrays, each memory cell array including a plurality of word lines, a plurality of bit lines intersecting the plurality of word lines, and a plurality of binary-data holding memory cells arranged at the intersections of the word lines and the bit lines; and a control unit operative to set the address space required for access to the memory cells, based on a control signal, and switch between a first operating mode and a second operating mode having a smaller number of accessible memory cells than the first operating mode.

In yet another aspect the present invention provides a semiconductor memory device, comprising: a memory cell array including a plurality of word lines, a plurality of bit lines intersecting the plurality of word lines, and a plurality of binary-data holding memory cells arranged at the intersections of the word lines and the bit lines; and a control unit operative to set the address space required for access to the memory cells, based on a control signal, and switch between a first operating mode and a second operating mode having a larger number of memory cells for use in 1-bit storage than the first operating mode.

### BRIEF DESCRIPTION OF THE DRAWINGS

FIGS. 1A-1E are block diagrams of a memory device according to a first embodiment of the present invention.

FIGS. 2A-2D are brief diagrams showing memory usage areas in the memory device according to the present embodiment.

FIG. 3 is a block diagram of a clock tree and the periphery in the memory device according to the present embodiment.

FIG. 4 is a block diagram of redundancy circuits and the periphery in the memory device according to the present embodiment.

FIG. 5 is a brief diagram of redundancy replacing in the memory device according to the present embodiment.

FIG. 6 is a brief diagram of data copy in a memory device according to a second embodiment of the present invention.

FIGS. 7A and 7B are diagrams showing memory cell arrays before and after 2-cell/bit operation switching in the memory device according to the present embodiment.

FIGS. 8A and 8B are diagrams showing memory cell arrays before and after 4-cell/bit operation switching in the memory device according to the present embodiment.

FIGS. 9A and 9B are diagrams showing memory cell arrays before and after 2-cell/bit operation switching in the memory device according to the present embodiment.

FIG. 10 is a brief diagram showing word line activated situations before and after multi-cell/bit operation switching in the memory device according to the present embodiment.

FIGS. 11A-11C are diagrams showing address assignments in the memory device according to the present embodiment.

FIG. 12 is a block diagram showing a portion associated with the data copy function of the memory device according to the present embodiment.

FIG. 13 is a diagram showing waveforms at the time of data copy in the memory device according to the present embodiment.

FIG. 14 is a diagram showing waveforms at the time of multi-cell/bit operation in the memory device according to the present embodiment.

FIGS. 15A and 15B are circuit diagrams showing row address mask circuits in the memory device according to the present embodiment.

FIGS. 16A and 16B are diagrams showing mode switching procedures in the memory device according to the present embodiment.

FIGS. 17A and 17B are diagrams showing mode switching procedures in the memory device according to the present embodiment.

FIGS. 18A and 18B are diagrams showing mode switching procedures in the memory device according to the present embodiment.

FIG. 19 is a circuit diagram showing a refresh counter of the memory device according to the present embodiment.

FIG. 20 is a circuit diagram showing a mode switching control circuit of the memory device according to the present embodiment.

FIG. 21 is a diagram showing waveforms at the time of mode switching in the memory device according to the present embodiment.

FIG. 22 is a block diagram showing a sense amplifier enable activation timing switching circuit in the memory device according to the present embodiment.

FIGS. 23A and 23B are diagrams showing the timing of refresh in the memory device according to the present embodiment.

FIGS. 24A and 29B are brief diagrams showing redundancy utilizing methods in the memory device according to the present embodiment.

FIG. 25 is a diagram showing the timing of refresh in a memory device according to a third embodiment of the present invention.

FIG. 26 is a block diagram showing the memory device according to the present embodiment.

FIG. 27 is a diagram showing signals at the time of bank copy in the memory device according to the present embodiment.

FIG. 28 is a block diagram showing a read/write data control circuit in the memory device according to the present embodiment.

### DETAILED DESCRIPTION OF THE EMBODIMENTS

The embodiments of the invention will now be described below with reference to the drawings.

### First Embodiment

### System Outline

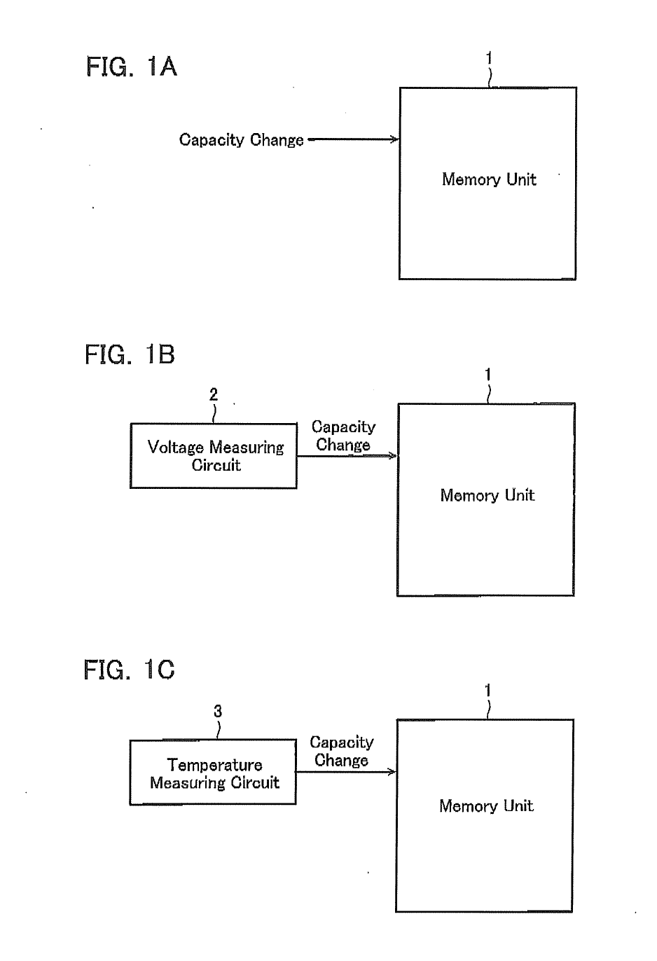

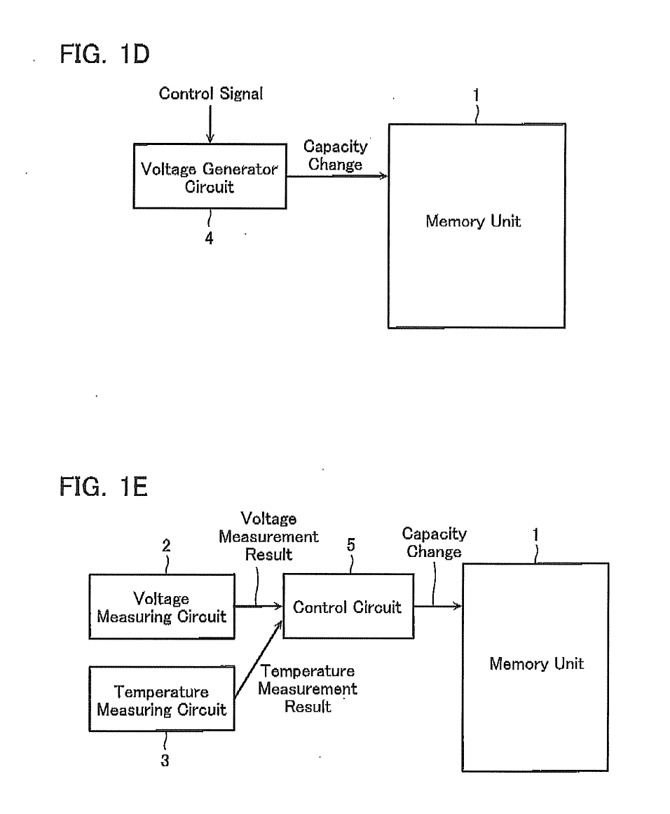

FIGS. 1A-1E are block diagrams of a memory device according to a first embodiment of the present invention.

The memory device of FIG. 1A comprises a memory unit 1 of which storage capacity can be changed in accordance with a capacity change signal sent from an external control means, not shown.

For example, when the memory device is required to operate on a lower source voltage than the rating, the control means sends a capacity change signal to reduce the storage capacity of a memory cell array, thereby allowing the memory device to operate with stability in an environment of low source voltage.

Even if the source voltage is supplied sufficiently, the reduced storage capacity can make the operating speed much higher.

The storage capacity of the memory device may be changed in accordance with variations in temperature. In a memory device that requires refreshing, such as a DRAM, a rise in temperature shortens the interval of refreshing, though, which can be prevented by reducing the storage capacity. On the other hand, a reduction in temperature elevates the threshold of a transistor in the memory device, thereby making peripheral circuits difficult to operate. Also in this case, though, a reduced memory capacity of the memory device ensures the operating margin.

The memory device shown in FIG. 1D further comprises a voltage measuring circuit 2 in addition to the memory device shown in FIG. 1A, which circuit is a control unit operative to measure the source voltage and send a capacity change signal to the memory unit 1 in accordance with a control signal generated on the basis of the measurement result.

In the case of this memory device, it is possible to change the storage capacity automatically in association with fluctuations in source voltage. Therefore, when the supplied source voltage lowers below a certain value, the storage capacity can be reduced automatically to ensure the operating margin accordingly.

The memory device shown in FIG. 1C further comprises a temperature measuring circuit 3 in addition to the memory device shown in FIG. 1A, which circuit is a control unit operative to measure the temperature and send a capacity change signal to the memory unit 1 in accordance with a control signal generated on the basis of the measurement result.

In the case of this memory device, it is possible to change the storage capacity automatically in association with fluctuations in temperature. Therefore, it is possible to ensure a certain operating margin over environmental variations, like in the case of the memory device in FIG. 1B.

The memory device shown in FIG. 1D comprises a memory unit 1, and a voltage generator circuit 4, which is a control unit operative to generate and supply a voltage for operating the memory unit 1. The voltage generator circuit 4 is controlled by a control signal given from external, not shown.

In this memory device, on receipt of the control signal, the voltage generator circuit 4 makes changes in storage capacity and then adjusts the supplied voltage. Therefore, after reducing the storage capacity by the control signal, lowering the supplied voltage makes it possible to ensure the operating margin and realize the fast operation together with the reduction in power consumption.

The configurations of the memory devices shown in FIGS. 1A-1D may be combined. One of such examples is a memory device shown in FIG. 1E.

This memory device comprises a memory unit 1, a voltage measuring circuit 2, and a temperature measuring circuit 3. It further comprises a control circuit 5 operative to send a capacity change signal to the memory unit 1 on the basis of the voltage measurement result sent from the voltage measuring circuit 2 and the temperature measurement result sent from the temperature measuring circuit 3.

In this case, it is possible to adjust the storage capacity in accordance with variations in source voltage and temperature and accordingly respond to environmental variations more flexibly than the memory devices shown in FIGS. 1A-1D.

In the following description, the state of normal operation is referred to as a “normal operation mode” (first operation mode) and the state of storage capacity reduced on low source voltage as a “low-capacity low-voltage operation mode” (second operation mode).

### [Usage Area in Memory Unit]

FIGS. 1A-1E have been used to describe the outline of the memory devices capable of making changes in storage capacity while the following description is given to the case where the storage capacity is reduced by restricting the usage area of the memory unit 1.

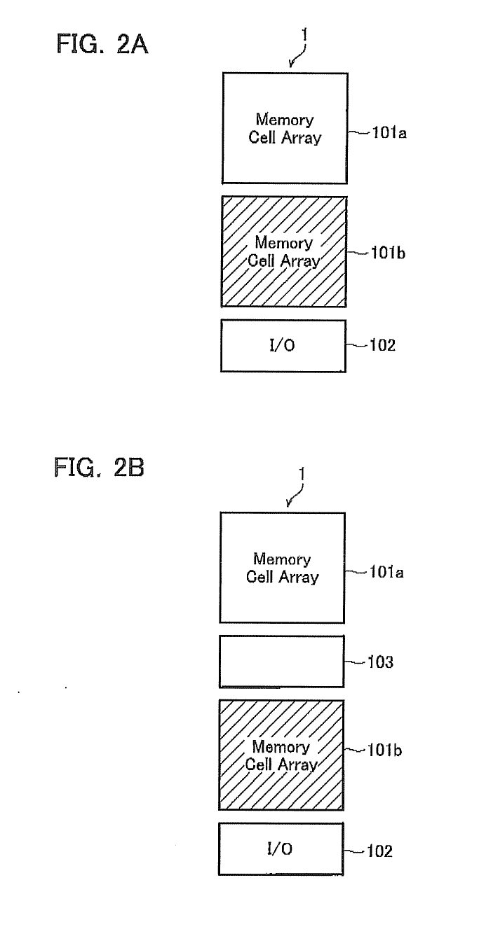

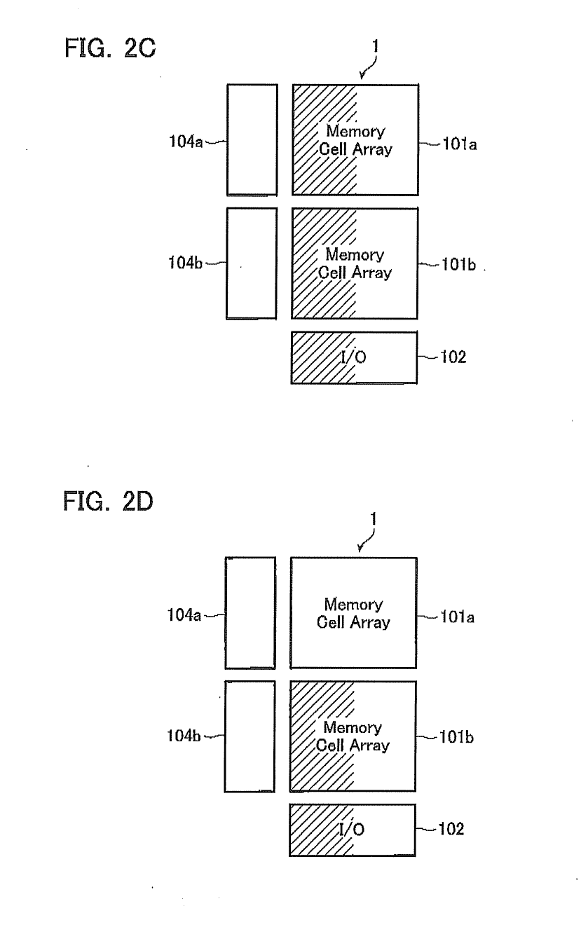

FIGS. 2A-2D are conceptual diagrams showing memory usage areas of the memory unit 1 in the memory device according to the present embodiment. The hatched portions in the figures show memory usage areas in the low-capacity low-voltage operation mode.

The memory unit 1 shown in FIG. 2A comprises memory cell arrays 101a and 101b each including a plurality of memory cells arranged in matrix, and an I/O unit 102 for use in control over data communications between the memory cell arrays 101a, 101b and the external. The memory cell array 101b has one end adjoining the memory cell array 101a, and the other end adjoining the I/O unit 102. Therefore, the memory cell array 101b is arranged closer to the I/O unit 102 than the memory cell array 101a.

The time required for data communications correlates the distance of the data path. Accordingly, in the case of the memory unit 1 of FIG. 2A, a memory cell located closer to the I/O unit 102 can send/receive data faster.

Therefore, even if the source voltage lowers below a certain threshold, it is possible to suppress the speed drop associated with the reduction in source voltage by using not the memory cell array 101a located far from the I/O unit 102 but the memory cell array 101b located closer to the I/O unit 102.

The threshold of the source voltage for switching from the normal operation mode to the low-capacity low-voltage operation mode may be set appropriately in accordance with the system requirement, and switching may be achieved in one stage or multiple stages. The storage capacity to be changed may be set appropriately in accordance with the system requirement, and changing may be achieved in one stage or multiple stages.

If the source voltage is low, the required performance may also be low. For example, the resolution may be low in image processing. In this case, the resolution of the image to be processed is low and the size of the required frame buffer is small. Accordingly, the storage capacity can be reduced without any problem. This is similarly found in other cases if the encoding algorithm in image processing is simple, or if the frame rate of motion pictures in motion picture processing is low, for example, and if only audio processing is executed without image processing in multimedia terminals or the like. If the memory device is used as a cache for a processor, the configuration parameter such as the number of cache ways may be varied. In this case, the quantity of used data is small in general when the required performance is low, and the cache may be made smaller without any problem.

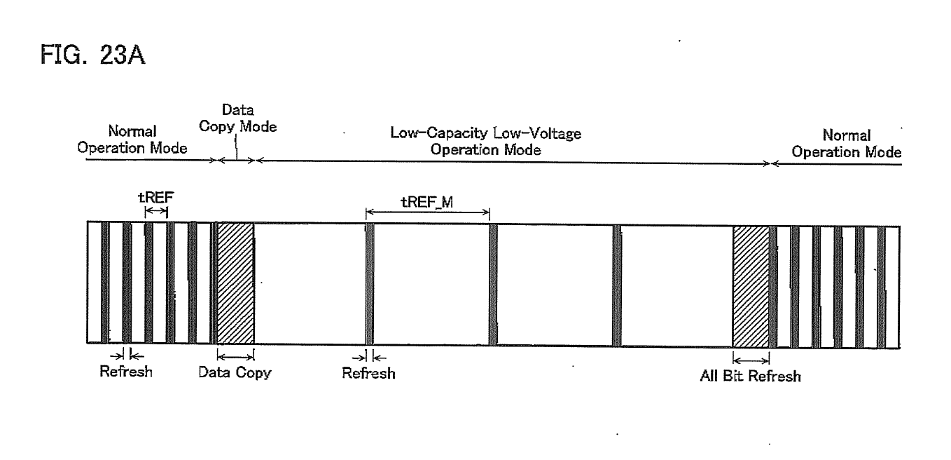

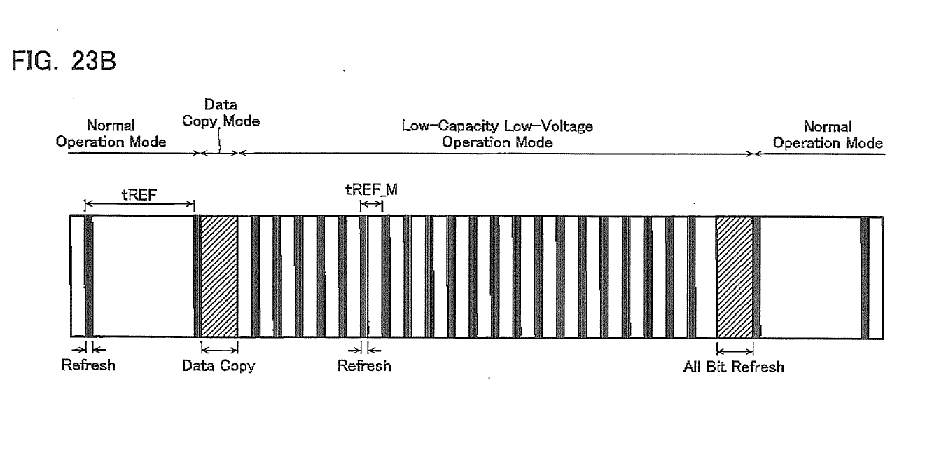

The memory unit 1 shown in FIG. 23 comprises a read/write data control circuit 103 between the memory cell arrays 101a and 101b at some midpoint in the data path between the memory cells and the I/O unit 102.

In the case of this memory unit 1, it uses only the memory cell array 101b located closer to the I/O unit 102 than the read/write data control circuit 103 in the low-capacity low-voltage operation mode. In this case, it is not required to drive the data line in the memory cell array 101a located far from the read/write data control circuit 103 seen from the I/O unit 102. Accordingly, it is possible to achieve faster operation of the memory unit 1 and further reduce power consumption.

Read/write data control circuits may be used in multiple stages. In a word, if there are three or more memory cell arrays, read/write data control circuits are arranged between the memory cell arrays. Even in such the configuration, when the source voltage lowers gradually, for example, prohibition of accesses to memory cells located far from the I/O unit in stages makes it possible to adjust the storage capacity and the source voltage more efficiently.

The memory unit 1 shown in FIG. 2C uses a hierarchical word line structure as the configuration of the memory cell arrays 101a and 101b. In this case, row decoders 104a and 104b operative to drive word lines are provided on the word lines at one end, not shown, in the memory cell arrays 101a and 101b.

In the case of this memory unit 1, it uses only areas of the memory cell arrays 101a and 101b located close to the row decoders 104a and 104b (hatched areas in FIG. 2C) to achieve faster operation in the low-capacity low-voltage operation mode. In this case, it is only required to drive part of the hierarchical word lines and accordingly it is possible to further reduce power. In general, as the word line is driven with a boosted voltage that is higher than the source voltage in many cases, the power reduction effect becomes much larger.

If the word line is driven with the boosted voltage and if the data to be written is at the source voltage level, the boosted voltage on the word line may be lowered in accordance with the source voltage to further reduce power consumption in the low-capacity low-voltage operation mode.

FIG. 2D is a combination of FIG. 2A and FIG. 2C, and it uses only areas of the more memory cell arrays 101a and 101b located close to the I/O unit 102 and the row decoders 104a and 104b (hatched areas in FIG. 2D) in the low-capacity low-voltage operation mode. In this case, it is possible to achieve much faster operation and larger reduction in power of the memory unit 1 than the cases of FIGS. 2A and 2C.

### (Supply of Clock to Memory Cell Array)

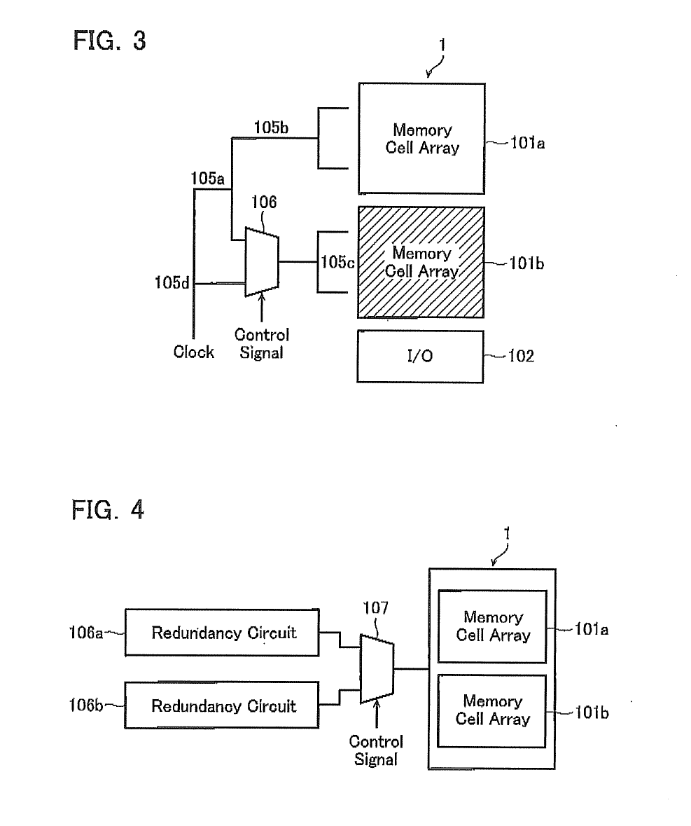

FIG. 3 is a block diagram of a clock tree and the periphery in the memory device according to the present embodiment.

The clock tree is a supply path of clocks to the memory cell arrays and generally provided on the periphery of the memory cell arrays. It has a root at the central position of the memory unit in the longitudinal direction or in the lateral direction, and extends into the memory cell arrays while branching.

If only some memory cell arrays are used, for example, it is not required to supply clocks over the entire path of the clock tree.

Therefore, the clock tree of the present embodiment is configured to shortcut part of the path in the low-capacity low-voltage operation mode so that clocks are supplied to only the memory cell array to be used.

Specifically, as shown in FIG. 3, the clock tree is provided around the memory cell arrays 101a and 101b and the position of the root 105a in the longitudinal direction locates at the midpoint of the memory cell arrays 101a and 101b. The clock tree is divided at the root 105a into two: one extends to the memory cell array 101a via a node 105b, and the other extends to the memory cell array 101b via a partial clock tree of which root is at a node 105c. A path change switch 106 is provided between the root 105a and the node 105c. The path change switch 106 is configured to have 2 inputs and 1 output. The first input is connected to the root 105a, and the second input is connected to a shortcut-use node 105d provided between the external and the root 105a. The output connected to the node 105c. The path change switch 106 is controlled with a control signal given from external to alternatively form either a path extending from the root 105a to the node 105c or a path extending from the node 105d to the node 105c directly without passing through the root 105a.

With this clock tree, when all the areas in the memory cell arrays 101a and 101b are used in the normal operation mode, clocks are supplied to the memory cell array 101a via the root 105a and the node 105b, and to the memory cell array 101b via the root 105a and the node 105c.

On the other hand, when the memory cell array 101b is used in the low-capacity low-voltage operation mode, clocks are supplied only to the memory cell array 101b via the nodes 105d, 105c. In this case, the path is made shorter than when clocks are supplied via the root 105a, and accordingly the delay can be reduced. In addition, no clock is supplied to the memory cell array 101a and accordingly power consumption can be reduced.

[Switching between Redundancy Circuits]

After the storage capacity is changed smaller, there is no need for the redundancy circuit to relieve a failure in a non-usage area. Therefore, in the present embodiment, this redundancy circuit is used to relieve a usage area in the low-capacity low-voltage operation mode.

FIG. 4 is a block diagram of redundancy circuits and the periphery in the memory device according to the present embodiment.

This memory device comprises memory cell arrays 101a and 102b, similar to FIG. 2A and so forth, and redundancy circuits 106a and 106b operative to hold redundancy information on the memory cell arrays 101. It also comprises a redundancy circuit change switch 107 operative to connect the redundancy circuits 106a and 106b to the memory cell arrays 101 selectively.

In the normal operation mode, these redundancy circuits 106a and 106b are used for the memory cell arrays 101a and 101b, respectively. On the other hand, when the memory cell array 101a is not used in the low-capacity low-voltage operation mode, for example, the redundancy circuit change switch 107 is switched in accordance with a control signal given from external so that the redundancy circuit 106a having been used to relieve the memory cell array 101a in normal operation is now used to relieve the memory cell array 101b.

In this case, the memory cell array 101a may be used to relieve a failure in the memory cell array 101b, which occurs due to lowering the source voltage or elevating the operating speed, for example. This makes it possible to achieve a much lower source voltage or a much higher operating speed.

The use of such the undesired redundancy circuit in relieving another area requires the redundancy circuits to be arranged not dispersedly but collectively.

A newly caused failed point may be programmed in a fuse or the like through the previous test of the memory device, similar to the redundancy information at the time of the normal operation mode.

The memory cell array for use in the low-capacity low-voltage operation mode may be selected so that the number of failed points caused in association with operation mode switching is minimized.

The above description was given to switching between the target areas relieved by the redundancy circuits on operation mode switching. A memory cell array itself may be utilized as a redundancy circuit if it is not used after storage capacity switching.

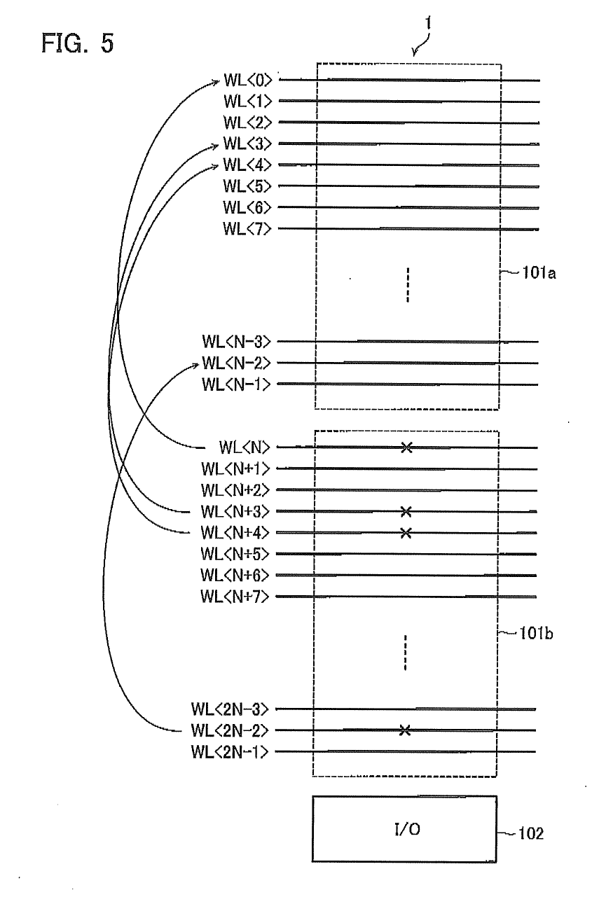

The outline of redundancy replacing in this case is shown in FIG. 5. The memory cell arrays 101a and 101b shown in FIG. 5 comprise N word lines WL each (N is a natural number). The mark x in the figure indicates a point of a failed memory cell.

In the case of FIG. 5, memory cells connected to word lines WL<N>, WL<N+3>, WL<N+4>, WL<2N−2> of the word lines WL in the memory cell array 101b used in the low-capacity low-voltage operation mode may be replaced with memory cells in the non-usage memory cell array 101a connected to word lines WL<0>, WL<3>, WL<4>, W<N−2> corresponding to failed memory cells in the memory cell array 101b.

As described, in the present embodiment, the usage area of the memory is restricted to achieve low power consumption, thereby providing a semiconductor memory device operable even in low source voltage environments.

### Second Embodiment

### Outline of Data Copy Function

The first embodiment describes a method of using only some memory cell arrays or using only a part of a memory cell array for reducing the storage capacity, ensuring the operating margin, and achieving low power consumption and speed improvement.

On the contrary, a memory device according to a second embodiment of the present invention executes 1-cell/bit operation to store 1-bit data in one memory cell in the normal operation mode, and executes multi-cell/bit operation to store 1-bit data in multiple memory cells in the low-capacity low-voltage operation mode. As a result, the usage area remains unchanged over the operation mode switching. In this case, the storage capacity lowers in the low-capacity low-voltage operation mode though multiple memory cells store data to improve the data retention. Therefore, even in low source voltage environments, the possibility of data destruction can be reduced to ensure stabilized operation.

At the time of switching from the normal operation mode to the low-capacity low-voltage operation mode, data stored in the memory unit is lost in the past. Therefore, it is required to restore the data before restarting operation after operation mode switching as a problem.

In the present embodiment, on switching from the normal operation mode to the low-capacity low-voltage operation mode, data in a memory cell used even after the low-capacity low-voltage operation mode is copied to a memory cell not used, thereby avoiding the loss of data.

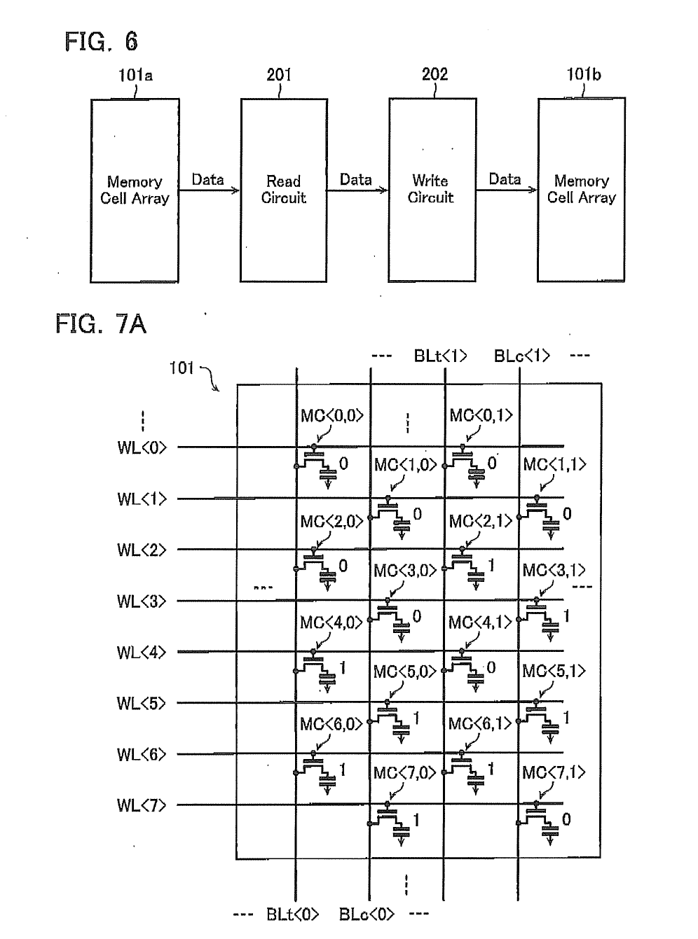

FIG. 6 is a brief diagram of data copy in the memory device according to the second embodiment of the present invention.

If the memory cell array 101a is used and the memory cell array 101b is not used in the low-capacity low-voltage operation mode, data copy is executed as follows. First, data read out of the memory cell array 101a is sent via a read circuit 201 to a write circuit 202. Thereafter, the data is sent from the read circuit 201 to the write circuit 202 and written by the write circuit 202 into a memory cell in the memory cell array 101b. A series of these operations are executed per macro composed of plural memory cell arrays 101.

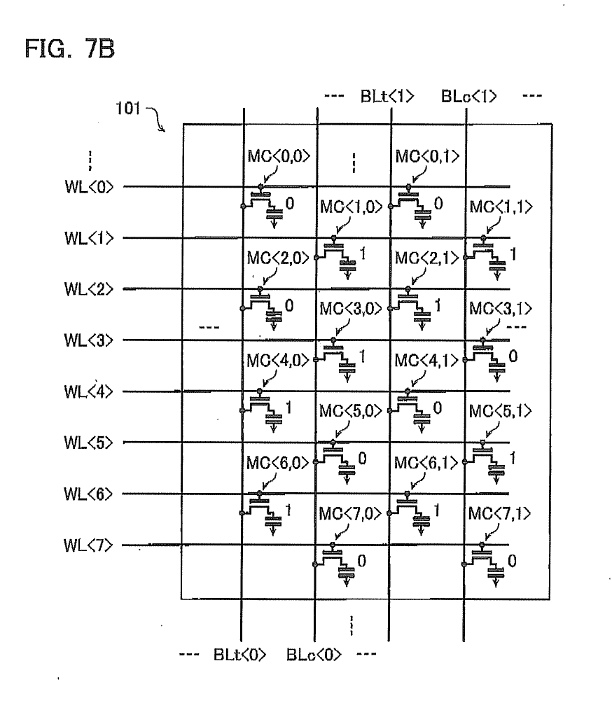

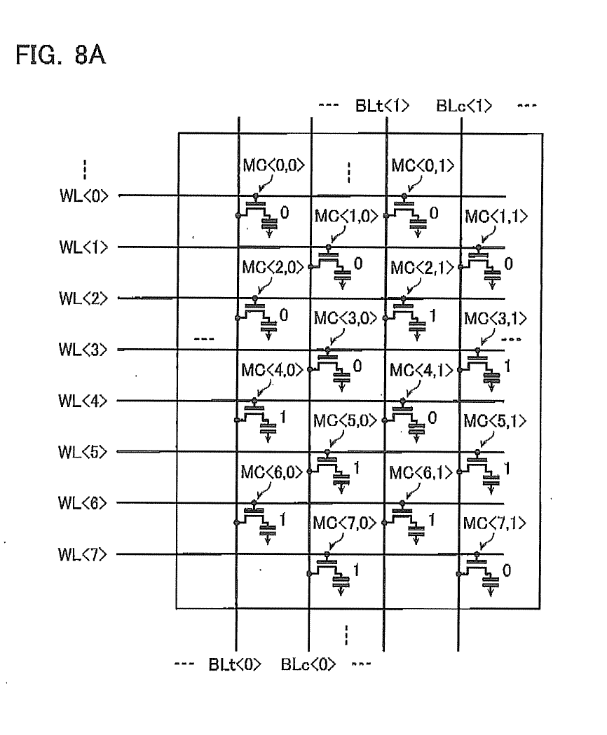

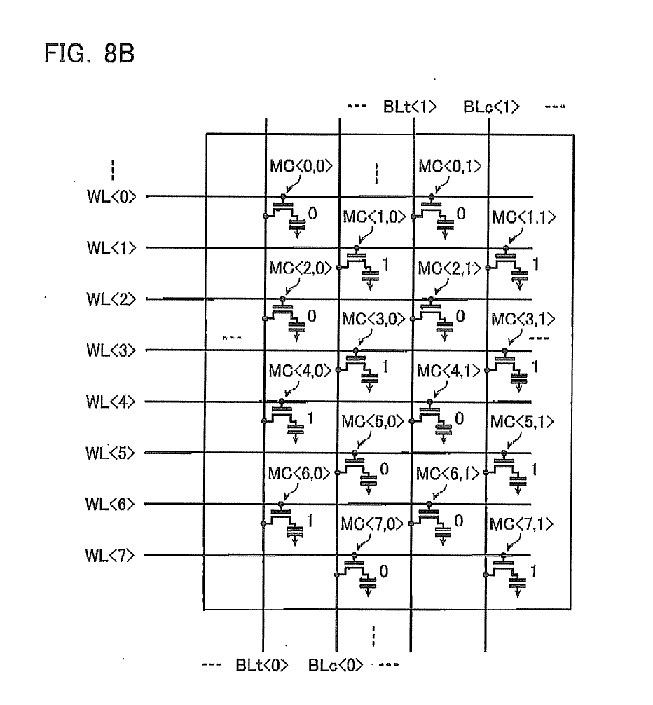

FIGS. 7-9 show the memory cell array 101 before and after operation mode switching in the memory device according to the present embodiment. These figures show examples of a DRAM and FIGS. 7 and 8 are directed in particular to examples of a DRAM having a folded bit line structure.

FIG. 7 shows an example of 1-cell/bit operation executed in the normal operation mode and 2-cell/bit operation executed in the low-capacity low-voltage operation mode. FIGS. 7A and 7B are diagrams showing pieces of data stored in memory cells at the time of the normal operation mode and the low-capacity low-voltage operation mode, respectively.

The memory cell array 101 comprises a plurality of word lines WL<0>, WL<1> and so on, and a plurality of bit lines BLt<0>, BLc<0>, BLt<1>, BLc<1> and so on, which intersect these word lines WL. At the intersection of the word line WL<i> (i is an even number) and the bit line BLt<j> (j is an integer), and at the intersection of the word line WL<i′> (i′=i+1) and the bit line BLc<j>, memory cells MC<i, j> and MC<i′, j> are arranged, respectively. Each memory cell MC includes a transistor having a drain connected to the bit line BL and a gate connected to the word line WL, and a capacitor connected between the source of the transistor and the ground line.

At the time of the normal operation mode, each memory cell MC stores “0” or “1” data as shown in FIG. 7A. For example, memory cells MC<0, 0>, MC<1, 0>, MC<2, 0> and MC<3, 0> store “0” while memory cells MC<4, 0>, MC<5, 0>, MC<6, 0> and MC<7, 0> store “1”, respectively.

When the memory device is switched to the low-capacity low-voltage operation mode to execute 2-cell/bit operation, the pieces of data held in the memory cells MC after operation mode switching become as shown in FIG. 7B.

In a word, the inverted data of the data in the memory cell MC<i, j> connected to the word line WL<i> and the bit line BLt<j> is copied in the memory cell MC<i′, j> connected to the word line WL<i′> and the bit line BLt<j>.

Specifically, the inverted data of the memory cells MC<0, 0> and MC<0, 1>, that is, “1” is copied in the memory cell MC<1, 0> and the memory cell MC<1, 1>.

Thus, copying the inverted data causes pieces of opposite logic data to appear on the bit lines BLt and BLc. Accordingly, a differential sense amplifier circuit can be utilized in data reading. Therefore, it is possible to compensate for the stability of data reading, which is lost due to the reduction in source voltage.

FIG. 8 shows an example of 1-cell/bit operation executed in the normal operation mode and 4-cell/bit operation executed in the low-capacity low-voltage operation mode. FIGS. 8A and 8B are diagrams showing pieces of data stored in memory cells at the time of the normal operation mode and the low-capacity low-voltage operation mode, respectively.

In this case, data in the memory cell MC<2i, j> is copied to the memory cell MC<2i+2, j>. Then, pieces of the inverted data of the data in these memory cell MC<2i, j>, MC<2i+2, j> are copied to memory cell MC<2i+1, j>, MC<2i+3, j>, respectively.

In this case, the data can be read out differentially using the bit lines BLt and Blc, like in the case of FIG. 7. In addition, it is considered that the quantity of charge held in the memory cell MC can be made almost double the case of FIG. 7 and accordingly the retention of the memory cell can be improved.

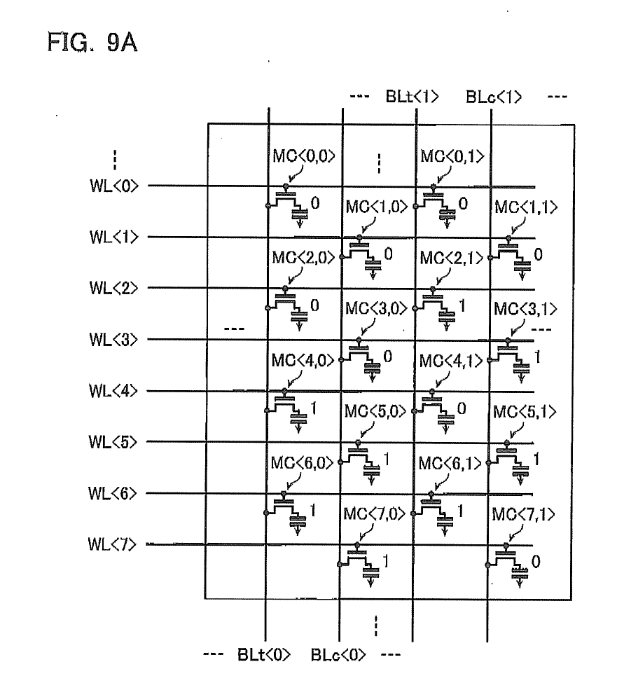

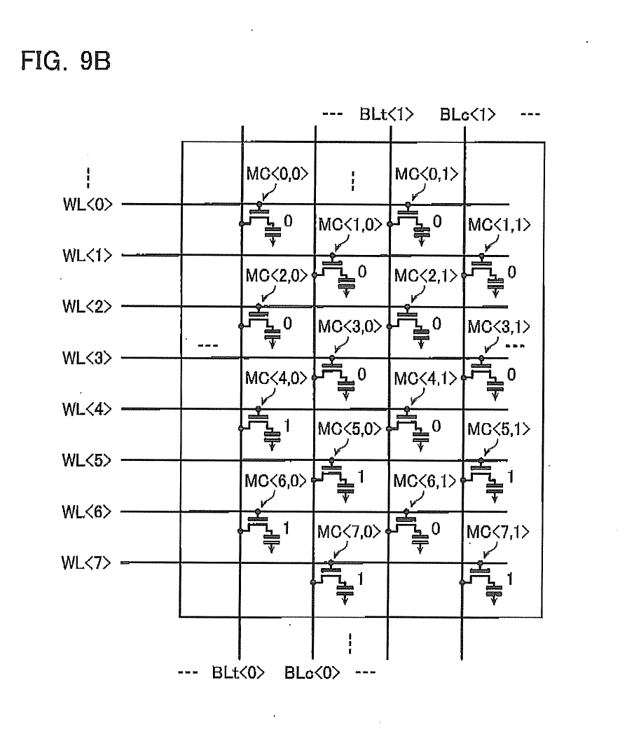

FIG. 9 shows an example of 1-cell/bit operation executed in the normal operation mode and 2-cell/bit operation executed in the low-capacity low-voltage operation mode. FIGS. 9A and 9B are diagrams showing pieces of data stored in memory cells at the time of the normal operation mode and the low-capacity low-voltage operation mode, respectively.

In the case of FIG. 9, pieces of data in the memory cells MC<2i, j>, MC<2i+1, j> are copied to the memory cell MC<2i+2, j> and MC<2i+3, j> as they are.

In this case, it is considered that the quantity of charge held in the memory cell MC can be made almost double the 1-cell/bit operation and accordingly the retention of the memory cell can be improved.

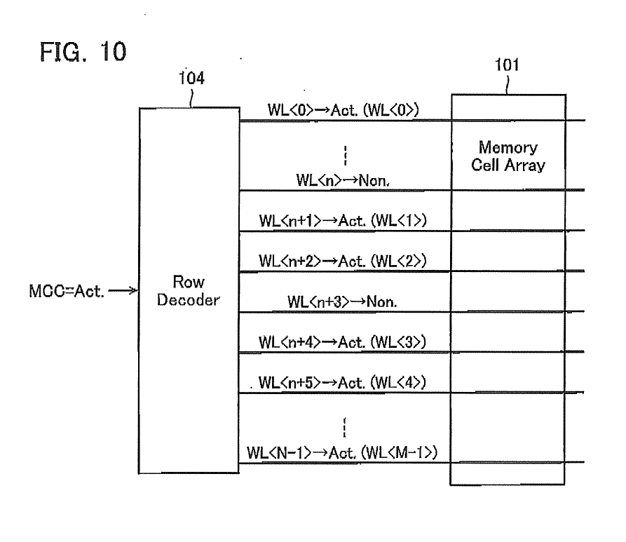

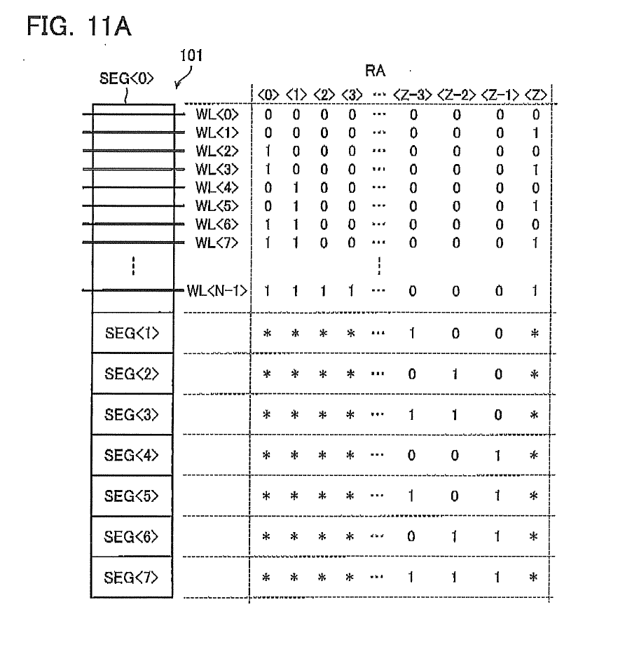

FIG. 10 is a brief diagram showing word line activated situations before and after multi-cell/bit operation switching in the memory device according to the present embodiment.

In this memory device, when a multi-cell operation signal MCC given from external is activated, the row decoder 104 activates M word lines WL (M is a natural number of 2 or more) of N word lines WL (N is a natural number of 2 or more) at the same timing or different timings. On the other hand, when the multi-cell operation signal MCC is not activated, the memory cell array 101 activates only a single word line WL. A series of these operations are controlled by the row decoder 104.

Thus, activating a certain number of word lines WL at the same timing or different timings makes it possible to realize the multi-cell/bit operation.

For example, it may be required to activate a total of 2 word lines WL<i>, WL<i+1> in the case of the memory device of FIG. 7, a total of 4 word lines WL<i> to WL<i+3> in the case of the memory device of FIG. 8, and a total of 2 word lines WL<i>, WL<i+2> in the case of the memory device of FIG. 9 at the same timing or different timings.

Thus, in accordance with the number of activated word lines WL, it is possible to adjust the number of memory cells MC used per one bit.

### [Address Assignment]

The following description is given to address assignments to memory cells in the memory device according to the present embodiment.

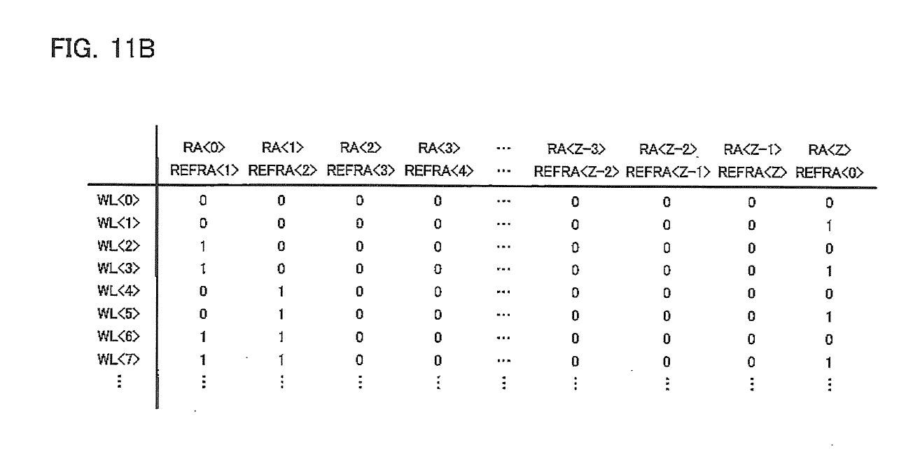

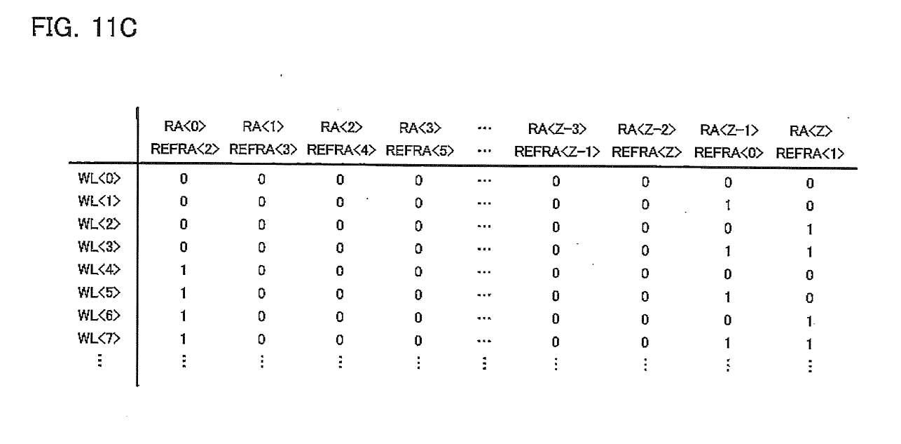

FIG. 11A shows an assignment of row addresses RA given from external to the word lines WL.

The example of FIG. 11A shows an address assignment for selecting one word line WL in the normal operation mode and two word lines WL in the low-capacity low-voltage operation mode.

The memory cell array 101 is divided into 8 segments SEG<8>, each comprising N word lines WL<0> to WL<N−1> (N is a natural number).

In this case, of a Z-bit row address RA (Z is a natural number), 3 bits RA<Z−1> to RA<Z−3> are used to designate the segment SEG, and RA<Z−4> to RA<0> to designate the word line WL. It is considered that two word lines WL having the same RA<Z−1> to RA<0> are adjacent to each other. Accordingly, in accordance with RA<Z>, it is possible to identify if the word line WL is connected to the memory cell used to store copy data.

Through the above address assignment, in accordance with the fact that “0” is assigned to the row address RA<Z> on switching from the normal operation mode to the low-capacity low-voltage operation mode or not, it is possible to identify if the data at this address is held or not. Accordingly, it is possible to control the memory device simpler.

FIG. 11B relates to a memory device that selects 2 word lines in the low-capacity low-voltage operation mode, and shows assignments of a row address RA to the word line WL and an internal refresh row address REFRA. The internal refresh row address REFRA is used in selecting a word line WL connected to a memory cell MC targeted for refresh.

Therefore, an internal row address RAIN, the row address RA, and the internal refresh row address have the following relations: RA<z−1>=REFRA<z> (where z=1−Z), RA<Z>=REFRA<0>.

FIG. 11C relates to a memory device that selects 4 word lines in the low-capacity low-voltage operation mode. In this case, the row address RA for use in selecting a word line WL in the low-capacity low-voltage operation mode is 2-bit less in number of bits than the normal operation mode.

Therefore, the row address RA and the internal refresh row address have the following relations: RA<z−2> REFRA<z> (where z=2−Z), RA<Z−1>=REFRA<0>, RA<Z>=REFRA<1>.

### [Method of Activating Word Line]

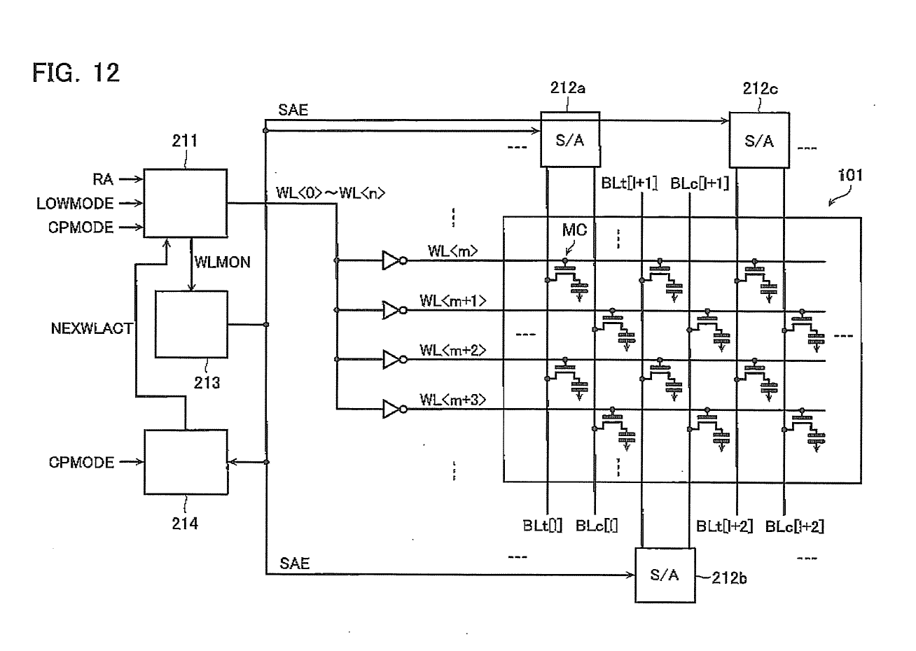

FIG. 12 is a block diagram showing a portion associated with the data copy function of the memory device according to the present embodiment.

This memory device comprises a memory cell array 101, which includes a plurality of word lines WL and a plurality of bit lines BLt, BLc mutually intersecting, and a plurality of memory cells MC provided at the intersections of these word lines WL and bit lines BLt, BLc.

It also comprises a local decoder/latch circuit 211 operative to select the word line WL in accordance with a row address RA, a low-capacity low-voltage operation mode signal LOWMODE signal, and a data copy mode signal CPMODE, and send a word line monitor signal WLMON for notifying the external about the associated timing. The low-capacity low-voltage operation mode signal LOWMODE is a signal that is activated when the memory device shifts to the low-capacity low-voltage operation mode. The data copy mode refers to the state in which, when the memory device shifts from the normal operation mode to the low-capacity low-voltage operation mode, it copies usage data in the low-capacity low-voltage operation mode to a memory cell that is used to store non-usage data. The data copy mode signal CPMODE is a signal that is activated to shift the memory device into the data copy mode.

The memory device shown in FIG. 12 further comprises a plurality of sense amplifiers 212 operative to sense/amplify data appeared on the bit lines BL, each provided for a bit line pair composed of complementarily paired bit lines BLt, BLc. It also comprises a delay circuit 213 operative to receive the word line monitor signal WLMON sent from the local decoder/latch circuit 211 and add a certain time delay to the signal to generate a sense amplifier activation signal SAE that activates the sense amplifier 212. It also comprises an additional delay circuit operative to generate the timing of activating the word line WL of copy destination in the copy mode based on the sense amplifier activation signal SAE, that is, a copy destination word line activation signal NEXWLACT and send it to the local decoder/latch circuit 211. The additional delay circuit 214 generates the copy destination word line enable signal NEXWLACT by adding a certain time delay to the sense amplifier activation signal SAE when the data copy mode signal CPMODE is activated.

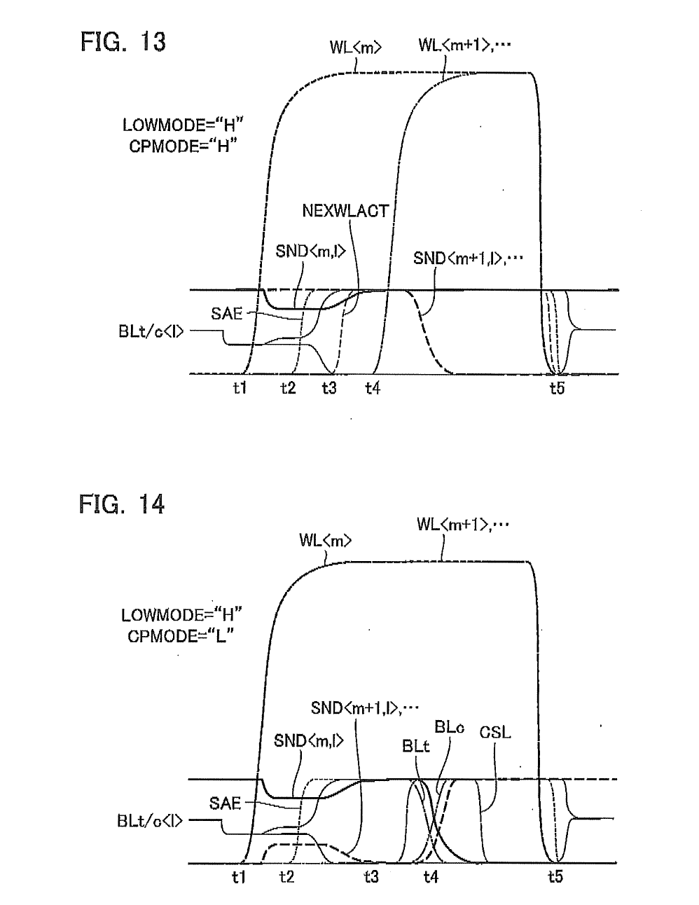

FIG. 13 is a diagram showing waveforms at the time of the data copy mode in the memory device.

In the memory device in the normal operation mode, when the low-capacity low-voltage operation mode signal LOWMODE and the data copy mode signal CPMODE are activated (“H”), the word line WL<m> connected to the memory cell MC for storing usage data is activated first at time t1. As a result, the data to be stored in this memory cell MC gradually appears on the complimentarily paired bit lines BLt and BLc. At that time, the storage node SND in the memory cell MC is pulled down for a moment in accordance with the voltage on the bit lines BLt and BLc.

Subsequently, at time t2, the sense amplifier activation signal SAE is activated (“H”) on the timing when data appears to some extent on the bit lines BLt and BLc, thereby activating the sense amplifier 212.

Subsequently, at time t3, the additional delay circuit 214 activates the copy destination word line activation signal NEXWLACT (“H”) with a certain delay after the timing of activating the sense amplifier activation signal SAE.

Subsequently, at time t4, the local decoder/latch circuit 211 on receipt of the copy destination word line activation signal NEXWLACT selects the word lines WL<m+1> of copy destination and so on. As a result, the storage node SND in the memory cell MC of copy destination is pulled down to “0” level opposite to data “1” held in the copy source memory cell MC of copy source.

Thereafter, at time t5, all word lines WL are brought into the non-selected state.

Thus, data copy is executed.

FIG. 14 is a diagram showing waveforms at the time of the low-capacity low-voltage operation mode in the memory device.

When the memory device shifts to the low-capacity low-voltage operation mode after completion of the data copy mode, the low-capacity low-voltage operation mode signal LOWMODE turns to “H” and the data copy mode signal CPMODE to “L”. In this case, at time t1, the local decoder/latch circuit 211 selects the word lines WL<m>, WL<m+1> at the same time. As a result, data in the selected memory cell gradually appears on the bit lines BLt, BLc.

Subsequently, at time t2, the sense amplifier activation signal SAE is activated (“H”) on the timing when data appears to some extent on the bit lines BLt and BLc, thereby activating the sense amplifier 212.

Subsequently, if writing is executed, the column select signal CSL turns to “H” at time t3. Now, it is assumed that 0 data is to be written on the storage node SND in the memory cell connected to the word line WL<m> via a cell transistor. Then, the data is first written on the bit lines BLt and BLc to invert them. In response to the inversion of the bit lines BLt and BLc, 0 data is written on the storage node SND in the memory cell MC connected to the word line WL<m> via a cell transistor. In contrast, 1 data is written on the storage node SND in the memory cell MC connected to the word line WL<m+1> via a cell transistor.

Thereafter, at time t5, all word lines WL are brought into the non-selected state.

### [Row Address Mask]

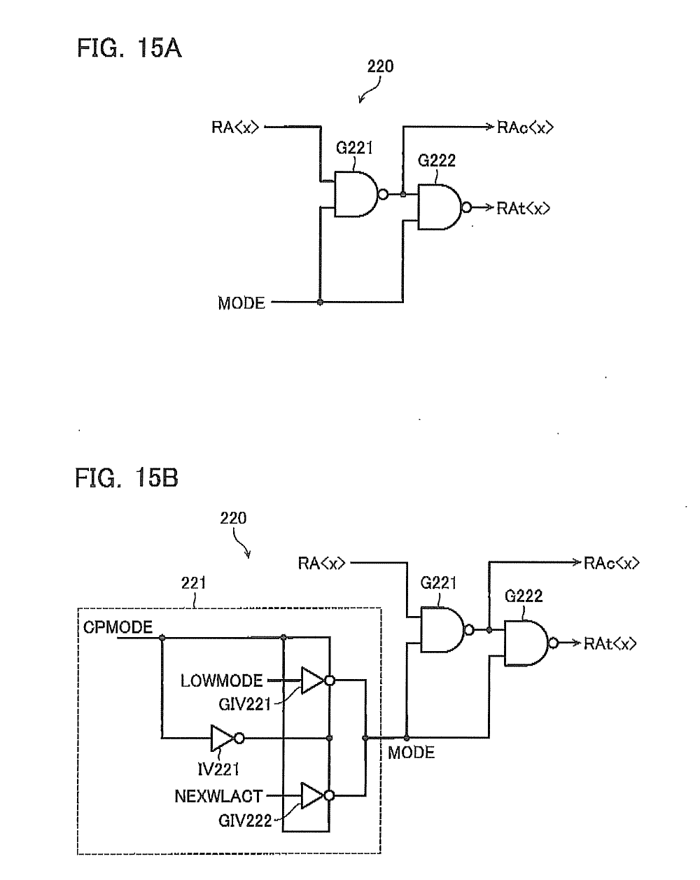

FIGS. 15A and 15B are circuit diagrams showing row address mask circuits contained in the local decoder/latch circuit 211 in the memory device according to the present embodiment. This row address mask circuit 220 is used to mask the row address, thereby activating the word line WL<m> connected to the memory cell of copy source and the word lines WL<m+1> and so on connected to the memory cell of copy destination at the same time.

The row address mask circuit 220 includes a NAND gate G221 operative to receive a row address RA<x> and a mode signal MODE for operation mode switching, and a NAND gate G222 operative to receive the output from the NAND gate G221 and the mode signal MODE. The output from the NAND gate G221 becomes the row address of copy source RAc<x> for selecting the word line WL connected to the memory cell MC of copy source, and the output from the NAND crate G222 becomes the row address of copy destination RAt<x> for selecting the word line WL connected to the memory cell MC of copy destination.

With this circuitry, when the mode signal MODE=“L” is established, RAt<x>=RAc<x>=“H” is established to activate the word lines WL<m>, WL<m+1> and so on at the same time.

FIG. 15B shows a data copy enabling circuit, which additionally includes a mode signal generator circuit 221 operative to generate the mode signal MODE for the row address mask circuit 220.

The mode signal generator circuit 221 includes a gated inverter GIV221, which is activated with the data copy mode signal CPMODE=“L” and operative to receive the low-capacity low-voltage operation mode signal LOWMODE, and a gated inverter GIV222, which is activated with the data copy mode signal CPMODE “H” and operative to receive the copy destination word line activation signal NEXWLACT. The outputs from these gated inverters become the mode signal MODE.

In the data copy mode, first, the data copy mode signal CPMODE “H” and the copy destination word line activation signal NEXWLACT=“L” are established to activate the word line WL of copy source. Next, the data copy mode signal CPMODE=“H” and the copy destination word line activation signal NEXWLACT=“H” are established to make the mode signal MODE “L”. As a result, the word line WL connected to the memory cell MC of copy destination is also activated.

On the other hand, in the low-capacity low-voltage operation mode, the data copy mode signal CPMODE “L” and the low-capacity low-voltage operation mode signal LOWMODE=“H” are established to make the mode signal MODE=“L”. As a result, the word lines WL<m>, WL<m+1> and so on are activated at the same time.

### [Operation Mode Switching]

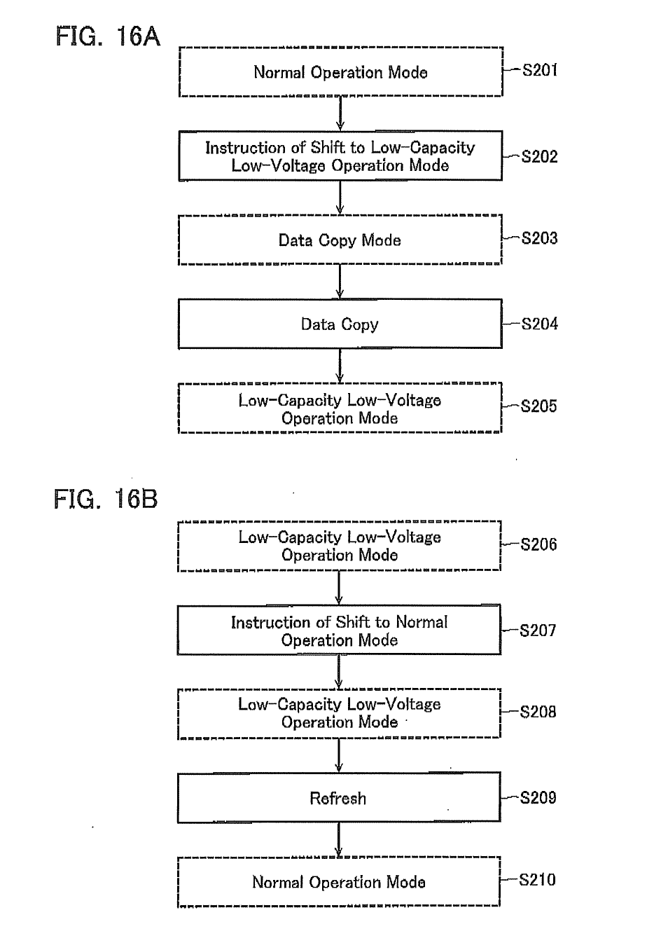

FIGS. 16-18 are diagrams showing mode switching procedures between the normal operation mode and the low-capacity low-voltage operation mode. With the procedures, mode switching can be executed without the loss of necessary data in the memory device.

FIG. 16A shows a procedure of switching from the normal operation mode to the low-capacity low-voltage operation mode.

The memory macro is in the normal operation mode (S201).

Then, the low-capacity low-voltage operation mode signal LOWMODE is activated (S202). As a result, the memory macro shifts to the data copy mode (S203) to execute data copy (S204).

Thereafter, the memory macro shifts to the low-capacity low-voltage operation mode (S205).

FIG. 16B shows a procedure of switching from the low-capacity low-voltage operation mode to the normal operation mode.

The memory macro is in the low-capacity low-voltage operation mode (S206).

Then, the low-capacity low-voltage operation mode signal LOWMODE is inactivated (S207). At this time, the memory macro remains in the low-capacity low-voltage operation mode (S208).

Thereafter, the memory cells are refreshed (S209) and the memory macro shifts to the normal operation mode (S210).

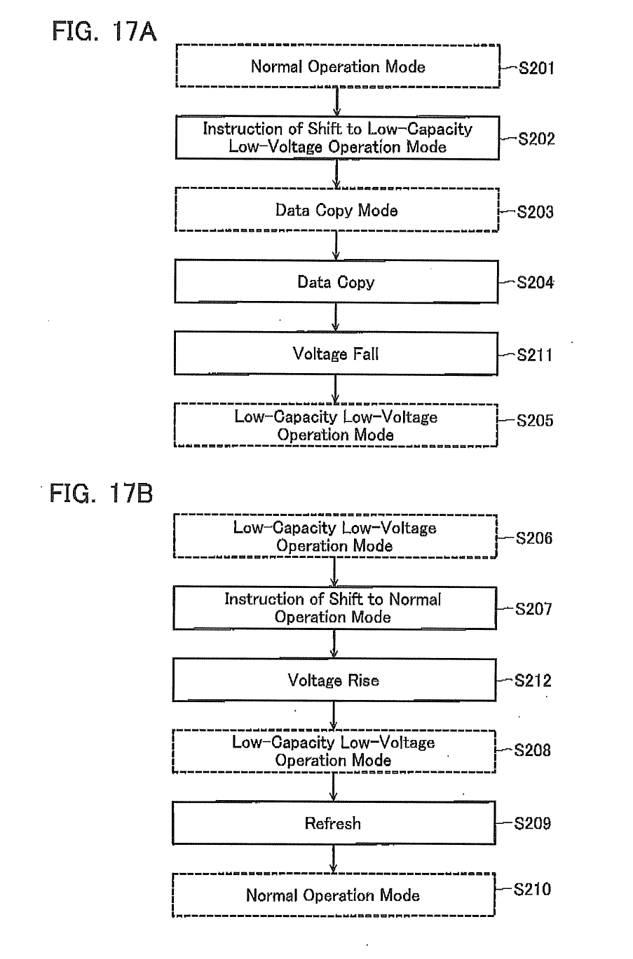

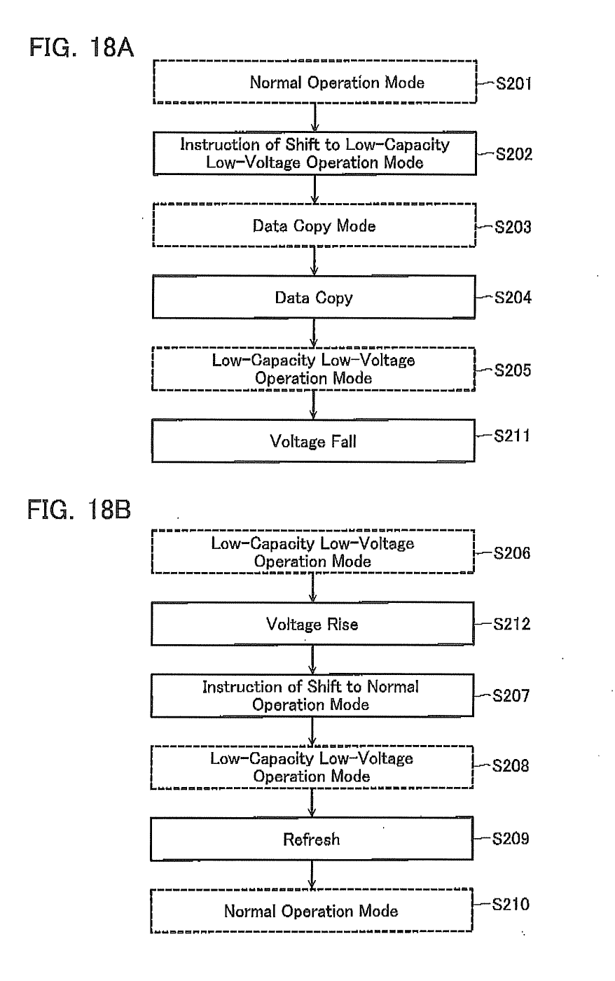

FIGS. 17 and 18 represent the fall and rise timings of the source voltage in addition to the procedure of FIG. 16.

On the shift from the normal operation mode to the low-capacity low-voltage operation mode, the fall of the source voltage (S211) causes no problem if data copy is completed. Therefore, it may be either immediately before the memory macro enters the low-capacity low-voltage operation mode (between S204 and S205) as shown in FIG. 17A, or after the shift to the low-capacity low-voltage operation mode (after S205) as shown in FIG. 18A.

On the other hand, on the shift from the low-capacity low-voltage operation mode to the normal operation mode, the rise of the source voltage (S212) causes no problem on operation if it may be before the memory macro enters the normal operation mode, that is, during the low-capacity low-voltage operation mode. Therefore, it may be either immediately after giving the instruction of the shift to the normal operation mode (after S207) as shown in FIG. 17A or before giving the instruction of the shift to the normal operation mode (before S207) as shown in FIG. 18A.

FIGS. 17 and 18 differ in fall and rise timings of the voltage, which, though, may be selected in accordance with applications and so forth.

### [Refresh Counter]

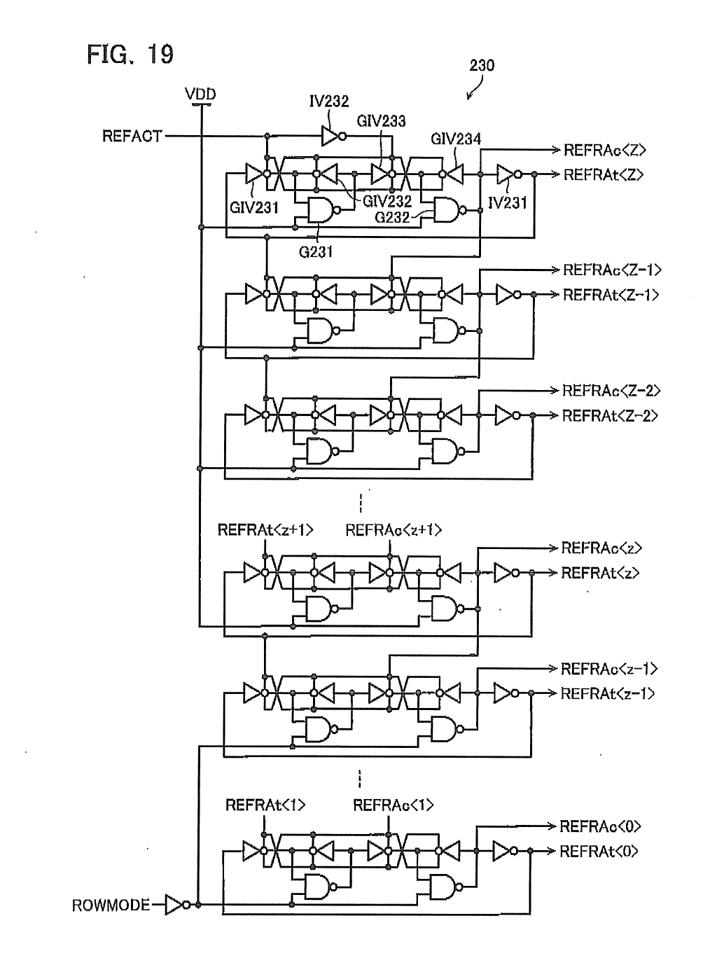

FIG. 19 shows a refresh counter 230 in the memory device according to the present embodiment, which corresponds to the normal operation mode, the data copy mode, and the low-capacity low-voltage operation mode. The refresh counter 230 is configured for the internal refresh row address REFRA having Z+1 bits (Z is an integer).

The refresh counter 230 comprises the following circuit unit per one bit of the internal refresh row address REFRA.

In a word, the circuit unit includes 4 gated inverters GIV231-GIV234, a NAND gate G231 having a first input to receive the output from the gated inverters GIV231 and GIV232, and a NAND gate G232 having a first input to receive the output from the gated inverters GIV233 and GIV234. The output from the NAND gates G231 and G232 is fed to the inputs of the gated inverters GIV232 and GIV234. The circuit unit also includes an inverter IV231 having an input to receive the output from the NAND gate G232. The output from the inverter IV231 is fed to the input of the gated inverter GIV231.

The outputs from the NAND gate G232 and the inverter IV231 become the internal refresh row addresses REFRAc and REFRAt.

The refresh counter 230 comprises such circuit units by the number of bits. The outputs from the NAND gate G232 and the inverter IV231 in each circuit unit are used as signals that alternately activate the gated inverters GIV231 and GIV234 and the gated inverters GIV232 and GIV233 in the next circuit unit.

The gated inverters GIV231-GIV234 in the circuit unit that provides the most significant bit, REFRAc<Z> and REFRAt<Z>, of the internal refresh row address REFRA are controlled with a refresh activation signal REFACT given from external. The refresh activation signal REFACT is a pulse signal, which is issued once a refresh. The refresh activation signal REFACT=“L” activates the gated inverters GIV231 and GIV234, and the refresh activation signal REFACT=“L” activates the gated inverters GIV232 and GIV233. Each input of the refresh activation signal REFACT updates the internal refresh row address REFRA.

The NAND gates G231 and G232 in the circuit units that provide the internal refresh row addresses REFRA<0>-<z−1> have second inputs, which receive the low-capacity low-voltage operation mode signal LOWMODE given from external via an inverter. On the other hand, the NAND gates G231 and G232 in the circuit units that provide the internal refresh row addresses REFRA<z>-<Z> have second inputs, which are fixed to the source voltage VDD.

In the normal operation mode, the low-capacity low-voltage operation mode signal LOWMODE=“L” is established, and in the data copy mode and the low-capacity low-voltage operation mode, the low-capacity low-voltage operation mode signal LOWMODE=“H” is established, thereby masking the lower bits in the internal refresh row address REFRA. In a word, the internal refresh row addresses REFRAt<0> to REFRAt<z−1> and REFRAc<0> to REFRAc<z−1> are fixed, and only the internal refresh row addresses REFRAt<z> to REFRAt<Z> and REFRAc<z> to REFRAc<Z> are updated per refresh.

### [Mode Switching Control Circuit]

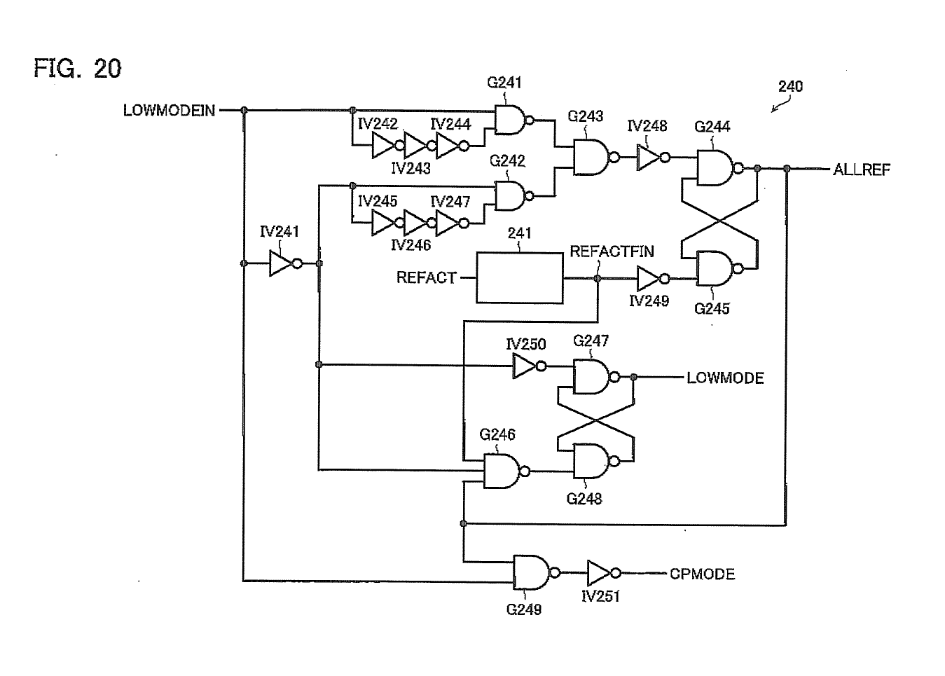

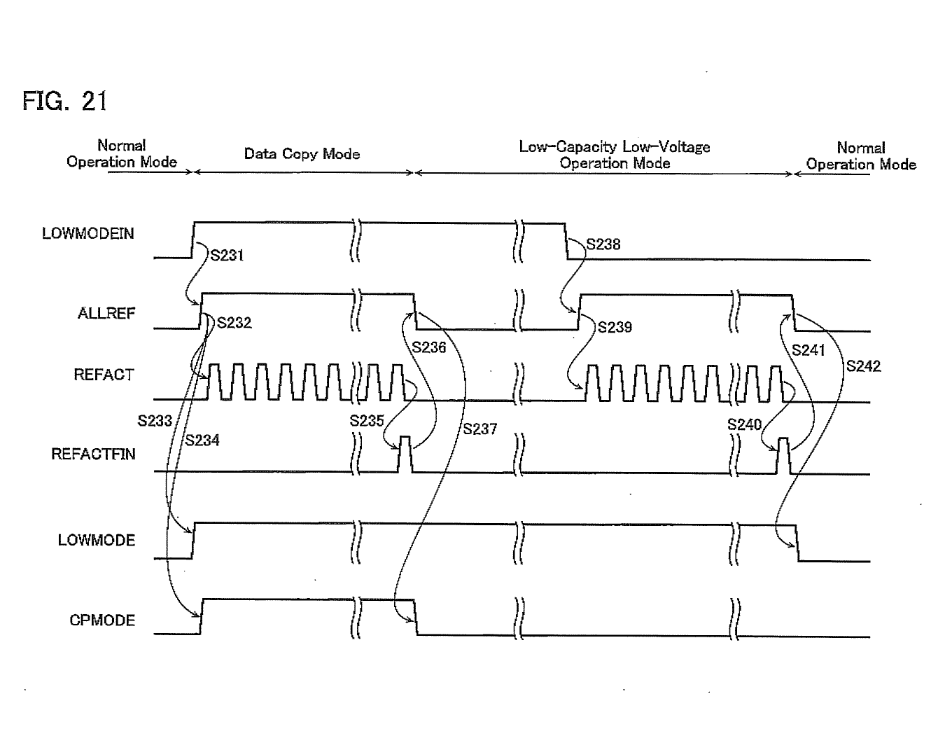

FIGS. 20 and 21 are used next to describe a method of controlling mode switching.

FIG. 20 shows a mode switching control circuit 240 operative to provide the low-capacity low-voltage operation mode signal LOWMODE, the data copy mode signal CPMODE, and an all bit refresh signal ALLREF for use in operation mode switching. The all bit refresh signal ALLREF is a signal used to cause refreshing (S209 in FIG. 16B) immediately before the shift from the low-capacity low-voltage operation mode to the normal operation mode, a signal used to cause copying at the time of the data copy mode. FIG. 21 shows signal patterns at the time of operation mode switching using the mode switching control circuit 240.

The mode switching control circuit 240 roughly comprises three sections: a section for generating the all bit refresh signal ALLREF, a section for generating the low-capacity low-voltage operation mode signal LOWMODE, and a section for generating the data copy mode signal CPMODE.

The section for generating the all bit refresh signal ALLREF includes a NAND gate G241, which has a first input to receive a low-capacity low-voltage operation mode shift signal LOWMODEIN that instructs switching to the low-capacity low-voltage operation mode, and a second input to receive the delayed and inverted signal of the low-capacity low-voltage operation mode shift signal LOWMODEIN via 3 inverters IV242-IV244, and a NAND gate G242, which has a first input to receive the inverted signal of the low-capacity low-voltage operation mode shift signal LOWMODEIN via an inverter IV241, and a second input to receive the delayed signal of the low-capacity low-voltage operation mode shift signal LOWMODEIN via 3 inverters IV245-IV247. The section also includes a NAND gate G243, which has a first and a second input to receive the outputs from the NAND gates G241 and G242. The section further includes a NAND gate G244, which has a first input to receive the output from the NAND gate G243 given via an inverter IV248. On the other hand, the section includes a refresh counter 241, which has an input to receive the refresh activation signal REFACT. The refresh counter 241 includes the refresh counter 230 shown in FIG. 19 and generates a refresh completion pulse signal REFACTIN that notifies the timing of completion of refreshing all bits. The section also includes a NAND gate G245, which has a second input to receive the refresh completion pulse signal REFACTIN given via an inverter IV249. The output from the NAND gate G245 is fed to the second input of the NAND gate G244, and the output from the NAND gate G244 is fed to the first input of the NAND gate G245. This configuration provides the output from the NAND gate G244 as the all bit refresh signal ALLREF.

The section for generating the low-capacity low-voltage operation mode signal LOWMODE includes a NAND gate G246, which has 3 inputs to receive the low-capacity low-voltage operation mode shift signal LOWMODEIN given via the inverter IV241, the refresh completion pulse signal REFACTIN, and the all bit refresh signal ALLREF. The section also includes a NAND gate G247, which has a first input to receive the low-capacity low-voltage operation mode shift signal LOWMODEIN given via 2 inverters IV241 and IV250, and a NAND gate G248, which has a second input to receive the output from the NAND gate G246. The output from the NAND gate G247 is fed to the first input of the NAND gate G248, and the output from the NAND gate G248 is fed to the second input of the NAND gate G247. This configuration provides the output from the NAND gate G247 as the low-capacity low-voltage operation mode shift signal LOWMODEIN.

The section for generating the data copy mode signal CPMODE includes a NAND gate G249, which has inputs to receive the low-capacity low-voltage operation mode shift signal LOWMODEIN and the all bit refresh signal ALLREF. The output from the NAND gate G249 is inverted at the inverter IV251 into a signal, which is provided as the data copy mode signal CPMODE.

The mode switching control circuit 240 thus configured is used in the shift from the normal operation mode to the low-capacity low-voltage operation mode, which is described with reference to FIG. 21.

First, when the low-capacity low-voltage operation mode shift signal LOWMODEIN is turned to “H”, the all bit refresh signal ALLREF rises from “L” to “H” (S231). While the all bit refresh signal ALLREF exhibits “H”, pulses of the refresh activation signal REFACT are continuously oscillated (S232). At this time, the low-capacity low-voltage operation mode shift signal LOWMODEIN and the data copy mode signal CPMODE rise from “L” to “H” (S233, S234). After completion of refreshing all bits, the refresh completion pulse signal REFACTIN turns from “L” to “H”. In response to this signal falling again to “L”, the all bit refresh signal ALLREF falls to “L” (S236) In response to the all bit refresh signal ALLREF falling to “L”, the data copy mode signal CPMODE falls to “L” (S237). As a result, the memory device exits from the data copy mode and shifts into the low-capacity low-voltage operation mode.

The following description is given to the shift from the low-capacity low-voltage operation mode to the normal operation mode.

First, the low-capacity low-voltage operation mode shift signal LOWMODEIN is fallen from “H” to “L”. As a result, the all bit refresh signal ALLREF rises from “L” to “H” (S238), and pulses of the refresh activation signal REFACT are continuously oscillated (S239). After completion of refreshing all bits, the refresh completion pulse signal REFACTIN rises from “L” to “H” (S290). In response to this signal falling again to “L”, the all bit refresh signal ALLREF falls to “L” (S241). In response to the all bit refresh signal ALLREF falling, the low-capacity low-voltage operation mode signal LOWMODE falls to “L” (S242) As a result, the memory device exits from the low-capacity low-voltage operation mode and shifts into the normal operation mode.

### [Generation of Sense Amplifier Activation Timing]

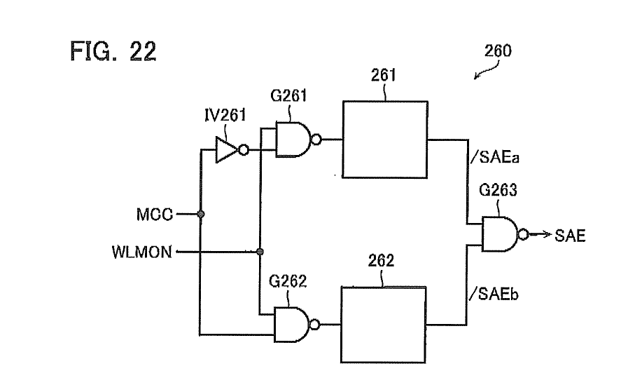

FIG. 22 shows a sense amplifier activation timing switching circuit 260 operative to generate the sense amplifier activation signal S.A.E. The circuit 260 is capable of switching between the activation timings of the sense amplifier activation signal SAE according to a multi-cell operation signal MCC.

This circuit comprises a NAND gate G261, which has inputs to receive a word line monitor signal WLMON and the multi-cell operation signal MCC given via an inverter W261, and a NAND gate G262, which has inputs to receive the word line monitor signal WLMON given via the inverter IV261 and the multi-cell operation signal MCC. The circuit also comprises delay circuits 261 and 262, which have inputs to receive the outputs from the NAND gates G261 and G262. The delay circuit 261 of those inverts the word line monitor signal WLMON and adds a certain time delay to generate a signal /SAEa when the multi-cell operation signal MCC is at “L”. On the other hand, the delay circuit 262 inverts the word line monitor signal WLMON and adds a certain time delay to generate a signal /SAEb when the multi-cell operation signal MCC is at “H” The circuit further comprises a NAND gate G263, which has inputs to receive the output /SAEa from the delay circuit 261 and the output /SAEb from the delay circuit 262.

This circuit 260 provides the inverted signal of the output /SAEa from the delay circuit 261 as the sense amplifier activation signal SAE when the multi-cell operation signal MCC=“L”. on the other hand, it provides the inverted signal of the output /SAEb from the delay circuit 262 as the sense amplifier activation signal SAE when the multi-cell operation signal MCC=“H”. Thus, it is possible to provide the sense amplifier activation signal SAE activated at different timings in accordance with the multi-cell operation signal MCC.

### [Refresh Signal Issue Timing]

Next, the timing of refreshing per operation mode is described using FIGS. 23A and 23B.

As shown in FIGS. 23A and 23B, in the normal operation mode, refreshing is executed at intervals of a certain time tREF. On the other hand, in the low-capacity low-voltage operation mode, refreshing is executed at intervals of a certain time tREF_M. With the intervals for refreshing in the normal operation mode made different from those in the low-capacity low-voltage operation mode in this way, the effect on refresh power in the low-capacity low-voltage operation mode can be expectedly reduced lower than the normal operation mode.

In the case of FIG. 23A, tREF<tREF_M is established while in the case of FIG. 23B, tREF>tREF_M is established. Of these cases, one that allows the power reduction effect to be expected much larger depends on the magnitude of the voltage fall in the low-capacity low-voltage operation mode.

### [Redundancy Utilization Method]

The following description is given to word line replacement when a non-usage area in the low-capacity low-voltage operation mode is used as redundancy for a usage area.

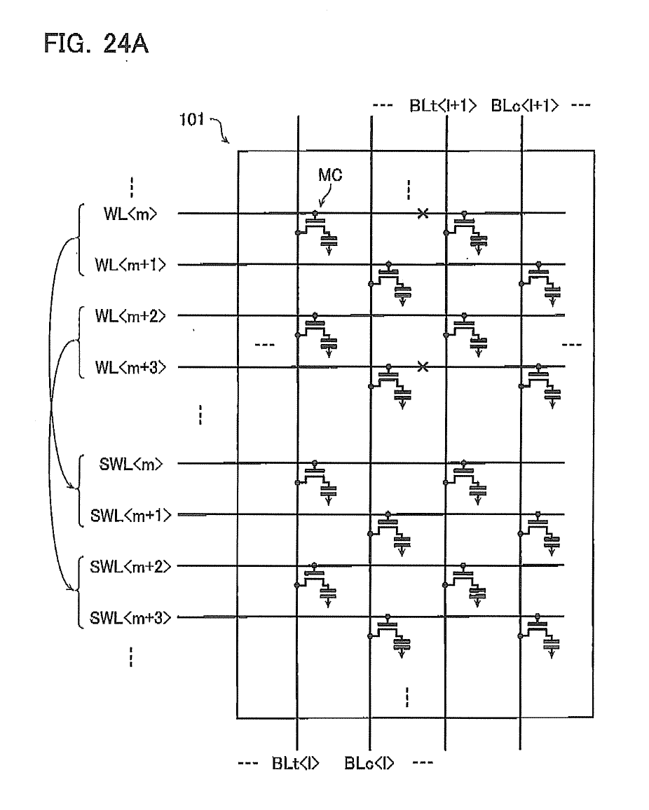

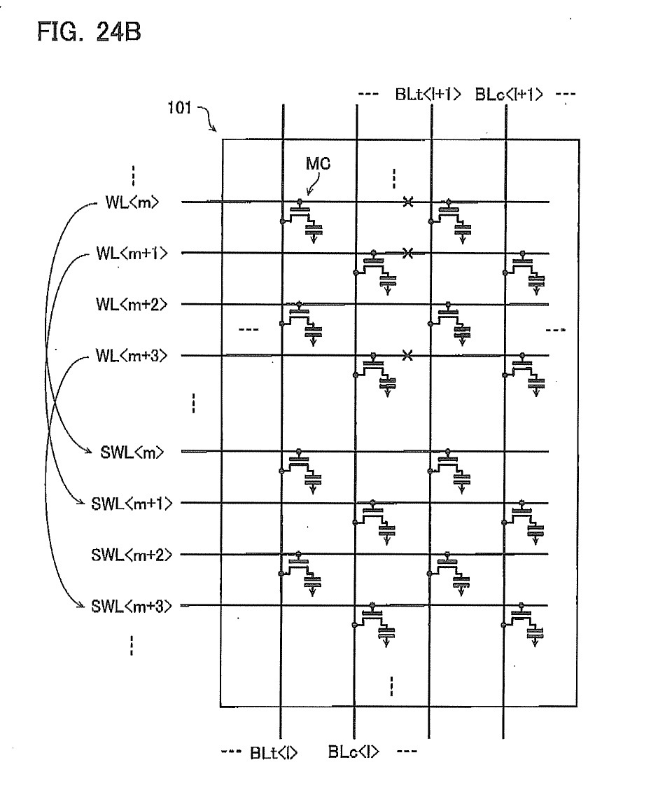

It is assumed that the memory device is in 2-cell/bit operation. Therefore, in the cases of FIGS. 24A and 24B, a word line pair composed of two adjacent word lines WL such as word lines WL<m> and WL<m+1> and word lines WL<m+2> and WL<m+3> are handled as a set. For the purpose of description, of plural word lines WL contained in the memory cell array 101, word lines WL located in the non-usage area in the low-capacity low-voltage operation mode are defined as spare word lines SWL.

In the case of FIG. 24A, if a certain word line WL has a failure, the set that contains the certain word line WL is always handled as the unit to be replaced with a set of two corresponding spare word lines SWL. For example, the word lines WL<m> and WL<m+3> are assumed to have failures as shown with the marks x in FIG. 24A. In this case, even if the word line WL<m+1> has no failure, the set of the word lines WL<m> and WL<m+1> is replaced with a set of corresponding spare word lines SWL<m> and SWL<m+1>. Similarly, even if the word line WL<m+2> has no failure, the set of the word lines WL<m+2> and WL<m+3> is replaced with a set of corresponding spare word lines SWL<m+2> and SWL<m+3>.

Thus, the DRAM of the folded bit line structure can maintain the relation between the word line WL, the memory cell MC and the bit line BL even after redundancy replacement.

On the other hand, in the case of FIG. 24B, if a certain word line WL has a failure, only the word line WL is replaced with a corresponding spare word line SWL. For example, the word lines WL<m>, WL<m+1>, WL<m+3> are assumed to have failures as shown with the marks x in FIG. 24B. In this case, the word lines WL<m>, WL<m+1>, WL<m+3> are replaced with spare word lines SWL<m>, SWL<m+1>, SWL<m+3>.

Thus, the DRAM of the folded bit line structure can maintain the relation between the memory cell MC connected to the bit line BL and the word line WL even after redundancy replacement.

As described above, the present embodiment makes it possible to enhance the stability of operation even at the time of low voltage. Accordingly, it is possible to realize a semiconductor memory device available at the time of normal and low voltage with simple circuitry.

### Third Embodiment

Memory cells in a DRAM require refreshing while the refreshing occupies a large proportion of standby current.

A technology of reducing the standby current is a partial refresh system, for example. In the partial refresh system, when the memory device is on standby, necessary data is stored in a special bank, and only this bank is refreshed. In this case, refresh intervals for memory cells are determined by the memory cell having the weakest leakage resistance. Accordingly, even during standby, it is required to maintain the refresh intervals similar to those on the normal operation.

Further, the reduction in refresh current requires the refresh intervals to be extended during standby. In this case, longer refresh intervals make data not be held. Therefore, a method is considered to relieve data in a memory cell having a weaker leakage resistance with ECC (Error Check and Correct). This method comprises generating parity data on entering standby, and checking and correcting the error on exiting from the standby mode to write back correct data into the memory cell. In this case, however, mounting the ECC function causes an increase in chip area as a problem. In addition, the parity data generation and the error checking and correction require a series of operations such as data read by the local sense amplifier, data transfer from the local sense amplifier to the ECC circuit, data transfer from the ECC circuit to the write driver, and data write by the write driver to be executed [Page Length×2 (Read and Write)×Row Address] times, which consumes considerable current. Further, the transition between the standby state and the normal state requires a period of time, [(Page Length×2 (Read and Write)+Row Address)×Cycle Time].

Therefore, to solve the above problem, the memory device according to the third embodiment of the present invention extends the refresh system by the multi-cell/bit operation at the time of the low-capacity low-voltage operation mode in the second embodiment and adds a bank copy function thereto, thereby realizing a bank partial refresh system.

### [Operational Outline of Memory Device]

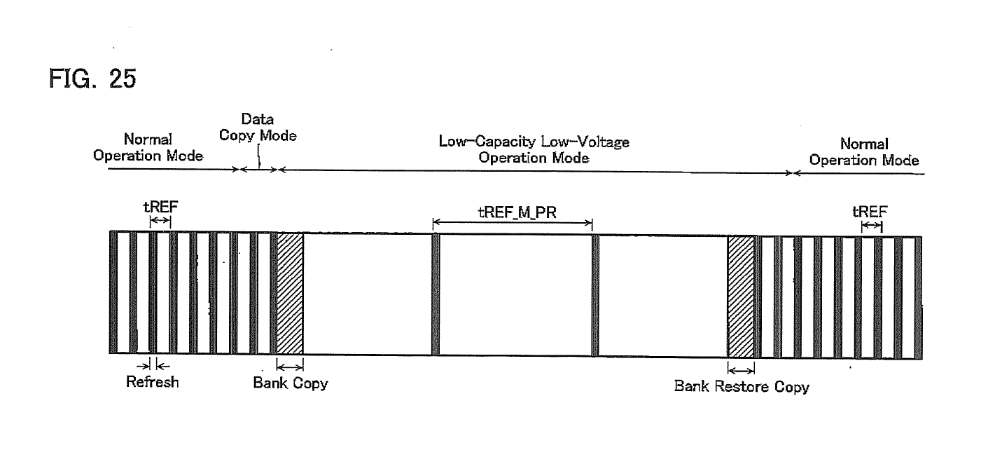

FIG. 25 is a brief diagram of the memory device according to the present embodiment.

At the time of the normal operation mode, the memory device refreshes memory cells in all banks at certain refresh intervals tREF.

On the shift, from the normal operation mode to the low-capacity low-voltage operation mode, the memory device once enters the data copy mode. In this mode, data in a bank used at the time of the low-capacity low-voltage operation mode is copied to another bank.

After completion of bank copy, the memory device shifts to the low-capacity low-voltage operation mode. In the low-capacity low-voltage operation mode, the retention is improved through the multi-cell/bit operation. Accordingly, refreshing is executed at refresh intervals tREF_M_PR, which are longer than the refresh intervals tREF at the time of the normal operation mode.

On the shift from the low-capacity low-voltage operation mode to the normal operation mode, the data copied at the data copy mode is restored to the bank of copy source.

As described above, the present embodiment makes it possible to extend the refresh intervals at the time of the low-capacity low-voltage operation mode without the use of ECC, thereby reducing the refresh current.

### [Bank Copy Function]

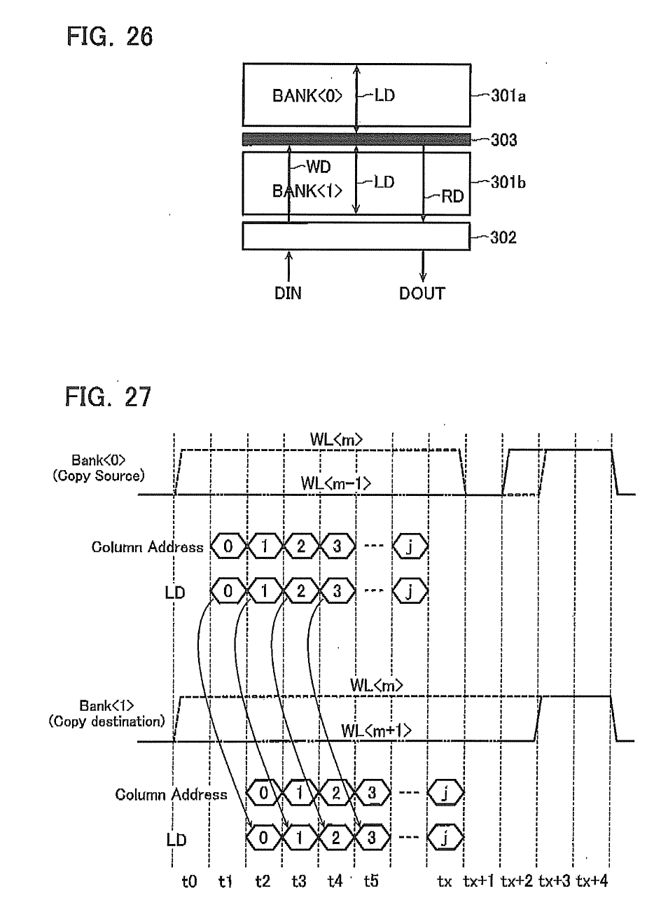

The bank copy function is described next with reference to FIGS. 26 and 27.

FIG. 26 is a block diagram of the memory device according to the present embodiment.

This memory device comprises two banks 301a (hereinafter referred to as a bank<0>) and 301b (hereinafter referred to as a bank<1>), and an I/O unit 302 operative to send/receive data to/from external via a data input PIN or DIN and a data output POUT or DOUT. A read/write control circuit 303 is provided between the bank<0> and the bank<1> to communicate data with the I/O unit 302 via a write data line WD and a read data line RD. Each bank 301 includes one or more memory cell arrays and sense amplifier circuits. Each sense amplifier circuit is connected via a local data line LD to the read/write control circuit 303, thereby sending/receiving data to/from the sense amplifier circuit.

FIG. 27 is a diagram showing the timings of signals at the time of bank copy in the memory device shown in FIG. 26.

The bank copy function first selects, at time t0, the word line WL<m> in the bank of copy source (bank<0> in the case of FIG. 27) and the word line WL<m> in the bank of copy destination (bank<1> in the case of FIG. 27) such that pieces of data in all memory cells MC connected to those word lines WL are cached into the corresponding sense amplifier circuits.

Subsequently, at time t1, data in the bank<0> at the column address 0 is cached via the local data line LD into the sense amplifier circuit in the bank<0>, then the data is read out and sent to the read/write control circuit 303.

Subsequently, at time t2, the data in the bank<0> at the column address 0 sent to the read/write control circuit 303 is written via the local data line LD into the sense amplifier circuit in the bank<1> at the column address 0 to overwrite the cache data. On the other hand, in the bank<0>, data at the column address 1 subsequent to the column address 0 is sent to the read/write control circuit 303.

Reading data from the bank<0> and writing data to the bank<1> executed from time t1 to t2 are repeated to complete 1-page copy <time tx>.

Thereafter, from time tx+2 to tx+3, the adjacent word line WL<m+1> is selected and data in the memory cell connected to the word line WL<m> is written into the memory cell connected to the word line WL<m+1> in the bank<0>, similar to the second embodiment.

A series of these operations are repeated to complete bank copy from the bank<0>.

In this case, it is not required on bank copy to drive large-capacity data lines such as the write data line WD and the read data line RD. In addition, it is possible to execute reading data from the bank<0> and writing data to the bank<1> at the same time. Therefore, processing in association with the multi-cell/bit operation shift can be achieved in a period of time, [(Page Length+Write Time to Adjacent Word Line WL×1/4 Row Address)×Cycle Time].

### [Read/Write Data Control Circuit]

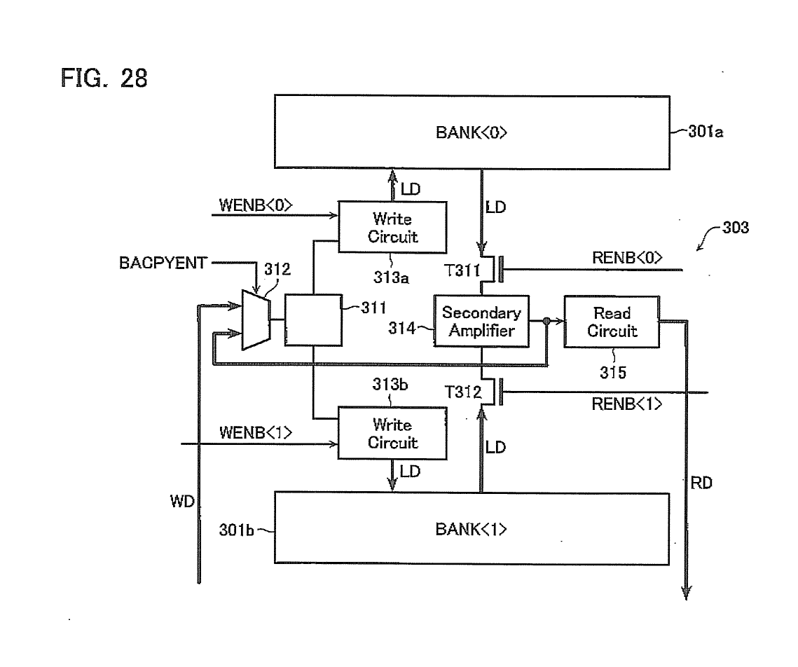

FIG. 28 is a block diagram showing a read/write data control circuit that realizes the bank copy function in the memory device according to the present embodiment.

This read/write control circuit 303 comprises a write data latch circuit 311 operative to hold write data, and write circuits 313a and 313b operative to receive the data held in the write data latch circuit 311 and send it via the local data line LD to the sense amplifiers in the bank<0> and the bank<1>. These write circuits 313a and 313b are activated with write enable signals WENB<0> and WENB<1> given from external, respectively. The read/write control circuit 303 also comprises a secondary amplifier 314 operative to sense/amplify data in the bank<0> and the bank<1>. The secondary amplifier 314 is connected to the bank<0> and the bank<1> via the local data lines LD having transistors T311 and T312 interposed therein and controlled with read enable signals RENB<0> and RENB<1>, respectively. The circuit also comprises a read circuit 315 operative to read out data from the secondary amplifier 314 and send it to external via the read data line RD. It further comprises a write data selection switch 312 operative to select between the output from the secondary amplifier 314 and the write data given from external via the write data line WD and send it to the write data latch circuit 311. Of the data from the secondary amplifier 314 and the data from the write data line WD, one to be selected at the write data selection switch 312 is determined based on a signal activated during bank copy, that is, a bank copy entry signal BACPYENT.

Copying from the bank<0> to the bank<1> is described next based on the circuit diagram of FIG. 28.

First, the data read out of the bank<0> is sent to the secondary amplifier 314 via the transistor T311 that is turned on with the read enable signal RENB<0>. Subsequently, this data is sensed and amplified at the secondary amplifier 314 and then sent to the write data selection switch 312. At this time, the bank entry signal BACPYENT is kept activated, and thus the write data selection switch 312 is allowed to select the data sent from the secondary amplifier 314 and send it to the write data latch circuit 311. Subsequently, the data in the write data latch circuit 311 is sent to the write circuits 313a and 313b. When the write enable signal WENB<1> is activated, the data sent from the write data latch circuit 311 is written into the bank<0> via the local data line LD.

On the other hand, in other cases than bank copy, for example, in writing data into the bank<0>, the bank copy entry signal BACPYENT is kept activated and the write enable signal WENB<0> is activated. In this case, first, write data given via the write data line WD is sent to the write data latch circuit 311 via the write data selection switch 312. Thereafter, this data is sent to the write circuit 313a and written into the bank<0> via the local data line LD.

On the other hand, in reading from the bank<0>, the read enable signal RENB<0> is kept activated and the transistor T311 is turned on. In this case, data readout of the bank<0> is sent via the local data line LD to the secondary amplifier 314 and sensed and amplified. Thereafter, this data is sent to the read circuit 315 and then read out to external via the read data line RD.

In the second embodiment, data in a memory cell MC on a certain word line WL is copied to a memory cell MC on an adjacent word line WL at the time of the low-capacity low-voltage operation mode to achieve 2-cell/bit. In this case, the leakage resistance of the memory cell is improved and the retention interval can be made larger though the data used in the low-capacity low-voltage operation mode must be written at every other word line WL. The partial refresh system, however, makes changes in refresh areas on a bank basis in general, and thus it causes complicacy on address assignments.

With this regard, the present embodiment makes it possible to simplify the transitions between the low-capacity low-voltage operation mode (standby state) and the normal operation mode (normal state). In addition, the retention improvement of the memory cell makes it possible to extend the refresh interval. Further, no problem occurs about the increase in chip area due to ECC mounting.

What is claimed is:

1. A semiconductor memory device, comprising:
a memory cell array including a plurality of word lines, a plurality of bit lines intersecting said plurality of word lines, and a plurality of binary-data holding memory cells arranged at the intersections of said word lines and said bit lines; and
a control unit operative to change in the storage capacity of said memory cell array and change in the address space required for access to said memory cell based on a control signal.

2. The semiconductor memory device according to claim 1, wherein said control unit includes a voltage measuring device operative to measure the source voltage for driving said semiconductor memory device and generate said control signal in accordance with said source voltage.

3. The semiconductor memory device according to claim 1, wherein said control unit includes a temperature measuring device operative to measure the environmental temperature and generate said control signal in accordance with said environmental temperature.

4. The semiconductor memory device according to claim 1, wherein said control unit includes a voltage generator circuit operative to adjust the drive voltage for said memory cell arrays based on said control signal given from external, said control unit operates to change in the storage capacity of said memory cell arrays after said voltage generator circuit adjusts the drive voltage for said memory cell array.

5. A semiconductor memory device, comprising:
a plurality of memory cell arrays, each memory cell array including a plurality of word lines, a plurality of bit lines intersecting said plurality of word lines, and a plurality of binary-data holding memory cells arranged at the intersections of said word lines and said bit lines; and
a control unit operative to set the address space required for access to said memory cells, based on a control signal, and switch between a first operating mode and a second operating mode having a smaller number of accessible memory cells than said first operating mode.

6. The semiconductor memory device according to claim 5, further comprising an I/O unit for use in data communications between the external and said memory cell,
wherein said control unit restricts access to said memory cell in a region far from said I/O unit among said plurality of memory cells in said second operating mode.

7. The semiconductor memory device according to claim 5, further comprising a decoder operative to select and drive said word line or bit line,
wherein said control unit restricts access to said memory cell in a region far from said decoder among said plurality of memory cells in said second operating mode.

8. The semiconductor memory device according to claim 5, further comprising a clock tree having a tree structure to distribute operating clocks to said plurality of memory cells,
wherein said clock tree includes a path change switch operative to shortcut between the root of the entire of said clock tree and the root of a partial clock tree, said partial clock tree being a part of said clock tree and used to supply said operating clocks to memory cells accessible in said second operating mode.

9. The semiconductor memory device according to claim 5, further comprising redundancy circuits for said memory cell arrays to hold redundancy information on respective ones of said memory cell arrays,
wherein said control unit selects a redundancy circuit for holding redundancy information on a certain inaccessible memory cell array and uses it in holding redundancy information on another accessible memory cell array in said second operating mode.

10. The semiconductor memory device according to claim 5, wherein said control unit selects one of said memory cells not used in data storage and uses it in storing redundancy information on another for use in data storage in said second operating mode.

11. The semiconductor memory device according to claim 10, wherein said memory cell array stores 1-bit data with a plurality of memory cells connected to a word line group composed of a certain number of said word lines,
wherein said redundancy information contains copy data from memory cells connected to a word line group to which said word line having a failed point belongs.

12. The semiconductor memory device according to claim 10, wherein said memory cell array stores 1-bit data with a plurality of memory cells connected to a word line group composed of a certain number of said word lines,
said redundancy information contains copy data from memory cells connected to said word line having a failed point.

13. A semiconductor memory device, comprising:
a memory cell array including a plurality of word lines, a plurality of bit lines intersecting said plurality of word lines, and a plurality of binary-data holding memory cells arranged at the intersections of said word lines and said bit lines; and
a control unit operative to set the address space required for access to said memory cells, based on a control signal, and switch between a first operating mode and a second operating mode having a larger number of memory cells for use in 1-bit storage than said first operating mode.

14. The semiconductor memory device according to claim 13, wherein said control unit copies data from a certain one of said memory cells to another on switching said first operating mode to said second operating mode.

15. The semiconductor memory device according to claim 13, further comprising banks each including two or more of said memory cell arrays,
wherein said control unit copies data from a certain one of said banks to another on switching said first operating mode to said second operating mode.

16. The semiconductor memory device according to claim 14, wherein said control circuit activates said word line for selecting said memory cell of copy source and then activates said word line for selecting said memory cell of copy destination on copying data between said memory cells.

17. The semiconductor memory device according to claim 16, wherein said word lines are assigned with respective row addresses required for selecting said word lines,
said word line connected to said memory cell of copy source and said word line connected to said memory cell of copy destination are determined by certain bits in said row addresses.

18. The semiconductor memory device according to claim 14, further comprising:
a sense amplifier circuit operative to sense data from said memory cell via said bit line;
a decoder operative to drive said word line;
a delay circuit operative to activate said sense amplifier circuit after a certain time elapsed since driving said word line; and
an additional delay circuit operative to notify said decoder about the timing after a certain time elapsed since activating said sense amplifier circuit,
wherein said decoder drives said word line connected to said memory cell of copy source and then drives said word line connected to said memory cell of copy destination on receipt of the notification from said additional delay circuit.

19. The semiconductor memory device according to claim 14, wherein said word lines are assigned with respective row addresses required for selecting said word lines,
further comprising a row address mask circuit operative to generate row addresses of said word lines connected to said memory cells of copy source and copy destination.

20. The semiconductor memory device according to claim 14, wherein said control unit makes changes in intervals of refreshing said memory cell on switching said first operating mode to said second operating mode.
